(19) United States
(12) Patent Application Publication
(10) Pub. No.: US 2017/0263710 A1
(43) Pub. Date: Sep. 14, 2017

(54) SEMICONDUCTOR ELEMENT, ELECTRIC EQUIPMENT, BIDIRECTIONAL FIELD EFFECT TRANSISTOR, AND MOUNTED STRUCTURE BODY

(71) Applicant: POWDEC K.K., Tochigi (JP)

(72) Inventors: Souta MATSUMOTO, Tochigi (JP); Shoko ECHIGOYA, Tochigi (JP); Shuichi YAGI, Tochigi (JP); Fumihiko NAKAMURA, Tochigi (JP); Hiroji KAWAI, Tochigi (JP)

(73) Assignee: POWDEC K.K., Tochigi (JP)

(21) Appl. No.: 15/310,184

(22) PCT Filed: Nov. 5, 2015
(86) PCT No.: PCT/JP2015/081102

§ 371 Date: Nov. 10, 2016

(30) Foreign Application Priority Data
Feb. 3, 2015 (JP) 2015-018985
Feb. 5, 2015 (JP) 2015-021026

(51) Int. Cl. H01L 29/06; H01L 29/20; H01L 29/205; H01L 27/08; H01L 29/778; H01L 29/872; H01L 27/098; H01L 29/812; H01L 29/10; H01L 29/207

(52) U.S. Cl. CPC H01L 29/0684; H01L 29/1058; H01L 29/2003; H01L 29/0634; H01L 29/205; H01L 29/207; H01L 29/7787; H01L 29/872; H01L 29/0657; H01L 27/098; H01L 29/812; H01L 27/0814

(57) ABSTRACT

Provided is a semiconductor element in which a two-dimensional hole gas with an enough concentration can exist, even though the p-type GaN layer is not provided on the topmost surface of the polarization super junction region.

The semiconductor element comprises a polarization super junction region comprising an undoped GaN layer 11 with a thickness a [nm] (a is not smaller than 10 nm and not larger than 1000 nm), an AlₓGa₁₋ₓN layer 12 and an undoped GaN layer 13. The Al composition x and the thickness t [nm] of the AlₓGa₁₋ₓN layer 12 satisfy the following equation

t≧α(a)x^{β(a)}

Where α is expressed as Log (α)=p₀+p₁ log (a)+p₂{log (a)}² (p₀=7.3295, p₁=−3.5599, p₂=0.6912) and β is expressed as β=p′₀+p′₁ log (a)+p′₂{log (a)}² (p′₀=−3.6509, p′₁=1.9445, p′₂=−0.3793).

### TECHNICAL FIELD

The present invention relates to a semiconductor element, electric equipment, a bidirectional field effect transistor, and a mounted structure body and, more particularly to a semiconductor element using a gallium nitride (GaN)-based semiconductor, electric equipment using the semiconductor element, a bidirectional field effect transistor, electric equipment using the bidirectional field effect transistor, and a mounted structure body comprising the semiconductorelement or the bidirectional field effect transistor.

### BACKGROUND ART

With increasing the importance of electric energy to realize energy saving society, in the twenty first-century, it is going to rely on electric power further. The key devices of electric and electronic equipment are semiconductor devices such as transistors and diodes. Therefore, energy saving characteristic of these semiconductor devices is very important. At present, a silicon (Si) semiconductor devices used as a power conversion device, but the silicon semiconductor device has been improved its performance to the limit of physical properties. Therefore, it is under difficult situation to save energy further.

For this, the research and development has been carried out intensively on the power conversion devices with a wide-gap semiconductor such as silicon carbide (SiC) and gallium nitride (GaN) in place of Si. Among them, GaN has remarkably better physical properties in power efficiency and voltage-resistance property than SiC. Therefore, the research and development for GaN-based semiconductor devices has been carried out energetically.

With regard to the GaN-based semiconductor device, a lateral type field effect transistor (FET), that is, a device with a structure formed with a transporting channel parallel to a substrate has been developed. For example, such a device is a device wherein upon a base substrate made of sapphire, SiC, etc., an undoped GaN layer is stacked with a few-μm-thick, and on it, an AlGaN layer with an Al composition of about 25% is stacked with about 25 to 30-nm-thick, and a two-dimensional electron gas (2DEG) formed at an AlGaN/GaN hetero-interface is used. The device is generally called a HFET (hetero-junction FET).

The AlGaN/GaN HFET has a technical problem of control of current collapse. The phenomenon of current collapse is a phenomenon that for the drain current at a low drain voltage up to several volts, the drain current after a high voltage is applied decreases. The phenomenon means in real circuits a phenomenon that the drain current during the turn-on period decreases when an operation voltage of switching becomes high. The current collapse is not a unique phenomenon in a GaN-based FET, but comes to appear remarkably with enabling to apply a high voltage between a source and a drain in the GaN-based FET, and is originally a phenomenon generally arising in horizontal type devices.

The cause of generation of current collapse is explained as follows. When a high voltage is applied between a gate and a drain of a FET, a high electric field area is generated just below the gate or just below the anode, and electrons transfer to the surface or surface vicinity of a part of the high electric field to be trapped. The source of electrons is electrons which drift on the surface of a semiconductor from a gate electrode, or channel electrons which transfer to the surface by a high electric field etc. By being biased to negative by the negative charges of the electrons, the electron concentration of the electronic channel decreases and the channel resistance goes up.

With regard to electrons generated by gate leakage, by making passivation by the dielectric film on the surface, electron transfer is limited and the current collapse is controlled. However, current collapse cannot be sufficiently controlled only by the dielectric film.

Therefore, focusing on that the current collapse results from a high electric field in the vicinity of a gate, a technology to control the intensity of electric field, especially peak electric field, has been developed. This is called the Field Plate (FP) technology, which is the heretofore known technology already in practical use in a Si-based or a GaAs-based FET (for example, see non-patent literature 1.). However, by the field plate technology, the electric field cannot be leveled over all the channel area. Also, a practical semiconductor device as a power device is applied a voltage of 600 V or more, therefore, the issue cannot be fundamentally solved even if the field plate technology is applied.

On the other hand, there is a super junction structure, one of the heretofore known technologies, which improves voltage resistance by equalizing the electric field distribution, and making the peak electric field unlikely occur (for example, see non-patent literature 2.). The super junction can withstand the applied voltage over the whole semiconductor with homogeneous electric field. The super junction is applied to a drift layer of a Si-MOS power transistor and a Si power diode with a vertical type or a horizontal type structure.

Also, there is the principle of polarization junction as a method to produce distribution of positive charge and negative charge as the same as the super junction without depending on the pn junction (for example, see patent literature 1.). Also, there is proposed a technology aiming high voltage resistance by making use of the polarization (for example, see patent literature 2.).

However, it is proved that the two-dimensional hole concentration of the polarization junction described in the patent literatures 1 and 2 is insufficient for high performance operation. Its reason is as follows. Negative polarization electric charge at the hetero-interface resulting in the two-dimensional hole at the hetero-interface is compensated by surface defects or surface levels. As a result, the band is pushed downwardly, resulting in the reduction of the concentration of the two-dimensional hole to be present at the AlGaN/GaN hetero-interface.

Therefore, a semiconductor device that can improve the problem of the polarization junction described in the patent literatures 1 and 2 was proposed (see patent literature 3 and non-patent literature 3.). The semiconductor device has typically a polarization super junction region with a structure in which an undoped GaN layer, an AlₓGa₁₋ₓN layer, an undoped GaN layer and a p-type GaN layer doped with Mg (magnesium) are stacked in order. In the semiconductor device, a two-dimensional hole gas is formed in the undoped GaN layer in the vicinity part of a hetero-interface between the AlₓGa₁₋ₓN layer and the undoped GaN layer thereon, and a two-dimensional electron gas is formed in the undoped GaN layer in the vicinity part of a hetero-interface between the AlₓGa₁₋ₓN layer and the undoped GaN layer thereunder at anon-operating time. More specifically, according to the semiconductor device, the surface GaN layer is doped with Mg to obtain a p-type GaN layer, and the band near the surface is lifted up by negative fixed electric charge of Mg acceptors, so that a sufficient concentration two-dimensional hole gas is formed in the AlGaN/GaN hetero-interface on the surface side. And a transistor utilizing essentially the polarization super junction effect was published for the first time (see non-patent literature 4.).

### PRIOR ART LITERATURE

### Patent Literature

[PATENT LITERATURE 1] Laid-open patent gazette 2007-134607
[PATENT LITERATURE 2] Laid-open patent gazette 2009-117485
[PATENT LITERATURE 3] International publication 2011/162243

### Non-Patent Literature

[NON-PATENT LITERATURE 1] Toshiba Review Vol. 59 No. 7 (2004) p. 35
[NON-PATENT LITERATURE 2] IEEE ELECTRON DEVICE LETTERS, VOL. 29, NO. 10, OCTOBER 2008, p. 1087
[NON-PATENT LITERATURE 3] Applied Physics Express vol. 3, (2010)
[NON-PATENT LITERATURE 4] Proceedings of the 23rd International Symposium on Power Semiconductor Devices & ICs May 23-26, 2011 San Diego. Calif.

### SUMMARY OF INVENTION

### Subjects to be Solved by Invention

According to the GaN-based semiconductor device using a polarization super junction, since it uses the principle as the same as a Si super junction device, it is possible to obtain a super high voltage resistance device more easily in principle than the field plate technology conventionally proposed. However, according to the examination originally conducted by the present inventors, the level of the Mg acceptor in the topmost p-type GaN layer is very deep as about 170-180 meV and the time constant of capture/release of holes is large, so there is fear of affecting high speed operation. Furthermore, especially in a polarization super junction field effect transistor, an edge of the p-type GaN layer on the side of the drain electrode in the polarization super junction region and the drain electrode are usually about μm apart and very close, so there is fear of lowering the voltage resistance between Mg acceptors in the p-type GaN layer and the drain electrode.

Therefore, the subject to be solved by the invention is to provide a semiconductor element and a bidirectional field effect transistor with high voltage resistance in which a two-dimensional hole gas with an effective concentration can exist, even though the topmost p-type GaN layer, which was considered to be indispensable in a conventional polarization super junction GaN-based semiconductor device, do not exist.

Another subject to be solved by the invention is to provide high performance electric equipment using the above semiconductor element or bidirectional field effect transistor.

Still another subject to be solved by the invention is to provide a mounted structure body comprising the above semiconductor element or bidirectional field effect transistor.

### Means to Solve the Subjects

In order to solve the objects, according to the invention, there is provided a semiconductor element, comprising:

a polarization super junction region comprising a first undoped GaN layer, an AlₓGa₁₋ₓN layer on the first undoped GaN layer and a second undoped GaN layer on the AlₓGa₁₋ₓN layer,

the Al composition x and the thickness t [nm] of the AlₓGa₁₋ₓN layer satisfying the following equation

t≧α(a)x^{β(a)}

where the thickness of the second undoped GaN layer is denoted as a [nm] (a is not smaller than 10 nm and not larger than 1000 nm),
α is expressed as

Log (α)=p₀+p₁ log (a)+p₂{log (a)}²

(p₀=7.3295, p₁=−3.5599, and p₂=0.6912) and
β is expressed as

β=p′₀+p′₁ log (a)+p′₂{log (a)}²

(p′₀=−3.6509, p′₁=1.9445, and p′₂=−0.3793).

In the semiconductor element, at a non-operating time, a two-dimensional hole gas is formed in the second undoped GaN layer in the vicinity part of a hetero-interface between the undoped AlₓGa₁₋ₓN layer and the second undoped GaN layer, and a two-dimensional electron gas is formed in the first undoped GaN layer in the vicinity part of a hetero-interface between the first undoped GaN layer and the undoped AlₓGa₁₋ₓN layer.

In the semiconductor element, no p-type GaN layer is provided on the second undoped GaN layer in the polarization super junction region. Preferably, the semiconductor element comprises a p-electrode contact region which is provided separately from the polarization super junction region. The polarization super junction region and the p-electrode contact region typically include the first undoped GaN layer, the AlₓGa₁₋ₓN layer and the second undoped GaN layer as common layers. The p-electrode contact region may further comprise a Mg-doped p-type GaN layer on the second undoped GaN layer, a p-type GaN contact layer which is doped with Mg heavier than the p-type GaN layer, provided in contact with the p-type GaN layer and a p-electrode which is in ohmic contact with the p-type GaN contact layer. The p-type GaN layer, the p-type GaN contact layer and the p-electrode are typically provided only in the p-electrode contact region. The p-type GaN contact layer may be provided in any way as far as it is in contact with the p-type GaN layer. For example, the p-type GaN contact layer may be stacked on the p-type GaN layer, or may be buried in the p-type GaN layer etc. With respect to the latter case, for example, a groove is provided in the AlₓGa₁₋ₓN layer, the second undoped GaN layer and the p-type GaN layer to a depth reaching at least the AlₓGa₁₋ₓN layer, the p-type GaN contact layer is buried inside the groove, so that the p-type GaN contact layer and the two-dimensional hole gas forms a junction.

According to the semiconductor element, typically, the first undoped GaN layer, the AlₓGa₁₋ₓN layer and the second undoped GaN layer are grown in order on a base substrate on which GaN-based semiconductor can be grown in C-plane orientation, or further the p-type GaN layer and the p-type GaN contact layer are grown in order.

The AlₓGa₁₋ₓN layer may be undoped, or an n-type or a p-type AlₓGa₁₋ₓN layer doped with donors (n-type impurities) or acceptors (p-type impurities), for example, a Si-doped n-type AlₓGa₁₋ₓN layer.

In the semiconductor element, as necessary, an intermediate layer which does not deteriorate characteristic of the polarization super junction may be provided between the first undoped GaN layer and the AlₓGa₁₋ₓN layer and/or between the second undoped GaN layer and the AlₓGa₁₋ₓN layer, for example, an AlᵤGa₁₋ᵤN layer (where 0<u≦1, u>x), typically undoped, for example, an AlN layer may be provided between the first undoped GaN layer and the AlₓGa₁₋ₓN layer and/or between the second undoped GaN layer and the AlₓGa₁₋ₓN layer. By providing the AlᵤGa₁₋ₓN layer between the second undoped GaN layer and the AlₓGa₁₋ₓN layer, permeation of the two-dimensional hole gas formed in the second undoped GaN layer in the vicinity part of the hetero-interface between the second undoped GaN layer and the AlₓGa₁₋ₓN layer into the AlₓGa₁₋ₓN layer side can be reduced, and mobility of holes can be increased dramatically. Also, by providing the AlᵤGa₁₋ₓN layer between the first undoped GaN layer and the AlₓGa₁₋ₓN layer, permeation of the two-dimensional electron gas formed in the first undoped GaN layer in the vicinity part of the hetero-interface between the first undoped GaN layer and the AlₓGa₁₋ₓN layer into the AlₓGa₁₋ₓN layer side can be reduced, and mobility of electrons can be increased dramatically. The AlᵤGa₁₋ₓN layer or the AlN layer may be generally sufficiently thin, for example, about 1 to 2 nm.

The semiconductor element can be used as various devices, typically, a field effect transistor (FET), a diode, etc.

In a case where the semiconductor element is a field effect transistor, the field effect transistor can be constructed, for example, as follows. That is, the second undoped GaN layer on the AlₓGa₁₋ₓN layer has an island shape, the p-type GaN layer and the p-type GaN contact layer are formed as a mesa, a source electrode and a drain electrode are formed on the AlₓGa₁₋ₓN layer so as to sandwich the second undoped GaN layer and the p-electrode forms a gate electrode. In a case where the semiconductorelement is a diode, the diode can be constructed, for example, as follows. That is, the second undoped GaN layer on the AlₓGa₁₋ₓN layer has an island shape, the p-type GaN layer and the p-type GaN contact layer are formed as a mesa, an anode electrode and a cathode electrode are formed so as to sandwich the second undoped GaN layer and the anode electrode and the p-electrode are electrically connected each other. Here, the anode electrode is provided so as to come in Schottky contact (or form a Schottky junction) with the AlₓGa₁₋ₓN layer and the cathode electrode is provided so as to come in ohmic contact with the AlₓGa₁₋ₓN layer. The anode electrode may be provided so as to come in Schottky contact with the two-dimensional hole gas formed in the first undoped GaN layer in the vicinity part of the hetero-interface between the first undoped GaN layer and the AlₓGa₁₋ₓN layer.

Furthermore, according to the invention, there is provided electric equipment, comprising:

at least a semiconductor element,

the semiconductor element being

a semiconductor element, comprising:

a polarization super junction region comprising a first undoped GaN layer, an AlₓGa₁₋ₓN layer on the first undoped GaN layer and a second undoped GaN layer on the AlₓGa₁₋ₓN layer,

the Al composition x and the thickness t [nm] of the AlₓGa₁₋ₓN layer satisfying the following equation

t≧α(a)x^{β(a)}

where the thickness of the second undoped GaN layer is denoted as a [nm] (a is not smaller than 10 nm and not larger than 1000 nm), α is expressed as

Log (α)=p₀+p₁ log (a)+p₂{log (a)}²

(p₀=70.3295, p₁=−3.5599, and p₂=0.6912) and
β is expressed as

β=p′₀+p′₁ log (a)+p′₂{log (a)}²

(p′₀=−3.6509, p′₁=1.9445, and p′₂=−0.3793).

Here, the electric equipment includes all equipment using electricity and their uses, functions, sizes, etc. are not limited. They are, for example, electronic equipment, mobile bodies, power plants, construction machinery, machine tools, etc. The electronic equipment are, for example, robots, computers, game equipment, car equipment, home electric products (air conditioners etc.), industrial products, mobile phones, mobile equipment, IT equipment (servers etc.), power conditioners used in solar power generation systems, power supplying systems, etc. The mobile bodies are railroad cars, motor vehicles (electric cars etc.), motorcycles, aircrafts, rockets, spaceships, etc.

Furthermore, according to the invention, there is provided a bidirectional field effect transistor, comprising:

a polarization super junction region and a p-electrode contact region which are provided separately each other,

the polarization super junction region, comprising a first undoped GaN layer, an AlₓGa₁₋ₓN layer on the first undoped GaN layer and an island-like second undoped GaN layer on the AlₓGa₁₋ₓN layer,

the Al composition x and the thickness t [nm] of the AlₓGa₁₋ₓN layer satisfying the following equation

t≧α(a)x^{β(a)}

where the thickness of the second undoped GaN layer is denoted as a [nm] (a is not smaller than 10 nm and not larger than 1000 nm),
α is expressed as

Log (α)=p₀+p₁ log (a)+p₂{log (a)}²

(p₀=7.3295, p₁=−3.5599, and p₂=0.6912) and
β is expressed as

β=p′₀+p′₁ log (a)+p′₂{log (a)}²

(p′₀=−3.6509, p′₁=1.9445, and p′₂=−0.3793),

the polarization super junction region and the p-electrode contact region including the first undoped GaN layer, the AlₓGa₁₋ₓN layer and the second undoped GaN layer as common layers, a first electrode and a second electrode constituting a source electrode or a drain electrode being provided on the AlₓGa₁₋ₓN layer so as to sandwich the second undoped GaN layer,

the p-electrode contact region, comprising:

a Mg-doped first p-type GaN layer on the second undoped GaN layer,

a Mg-doped second p-type GaN layer on the second undoped GaN layer, provided separately from the first p-type GaN layer,

a first p-type GaN contact layer which is doped with Mg heavier than the first p-type GaN layer, provided in contact with the first p-type GaN layer,

a second p-type GaN contact layer which is doped with Mg heavier than the second p-type GaN layer, provided in contact with the second p-type GaN layer,

a first p-electrode constituting a first gate electrode which is in ohmic contact with the first p-type GaN contact layer; and

a second p-electrode constituting a second gate electrode which is in ohmic contact with the second p-type GaN contact layer.

Furthermore, according to the invention, there is provided electric equipment, comprising:

one or more bidirectional switches,

at least one of the bidirectional switches being

a bidirectional field effect transistor, comprising:

a polarization super junction region and a p-electrode contact region which are provided separately each other,

the polarization super junction region, comprising a first undoped GaN layer, an AlₓGa₁₋ₓN layer on the first undoped GaN layer and an island-like second undoped GaN layer on the AlₓGa₁₋ₓN layer,

the Al composition x and the thickness t [nm] of the AlₓGa₁₋ₓN layer satisfying the following equation

t≧α(a)x^{β(a)}

where the thickness of the second undoped GaN layer is denoted as a [nm] (a is not smaller than 10 nm and not larger than 1000 nm),
α is expressed as

Log (α)=p₀+p₁ log (a)+p₂{log (a)}²

(p₀=7.3295, p₁=−3.5599, and p₂=0.6912) and
β is expressed as

β=p′₀+p′₁ log (a)+p′₂{log (a)}²

(p′₀=−3.6509, p′₁=1.9445, and p′₂=−0.3793),

the polarization super junction region and the p-electrode contact region including the first undoped GaN layer, the AlₓGa₁₋ₓN layer and the second undoped GaN layer as common layers,

a first electrode and a second electrode constituting a source electrode or a drain electrode being provided on the AlₓGa₁₋ₓN layer so as to sandwich the second undoped GaN layer,

the p-electrode contact region, comprising:

a Mg-doped first p-type GaN layer on the second undoped GaN layer,

a Mg-doped second p-type GaN layer on the second undoped GaN layer, provided separately from the first p-type GaN layer,

a first p-type GaN contact layer which is doped with Mg heavier than the first p-type GaN layer, provided in contact with the first p-type GaN layer,

a second p-type GaN contact layer which is doped with Mg heavier than the second p-type GaN layer, provided in contact with the second p-type GaN layer,

a first p-electrode constituting a first gate electrode which is in ohmic contact with the first p-type GaN contact layer; and

a second p-electrode constituting a second gate electrode which is in ohmic contact with the second p-type GaN contact layer.

The electric equipment using the bidirectional field effect transistor includes a matrix converter, a multi-level inverter, etc. in addition to those exemplified above.

Furthermore, according to the invention, there is provided a mounted structure body, comprising:

a chip constituting a semiconductor element; and

a mount board on which the chip is flip chip mounted,

the semiconductor element being

a semiconductor element, comprising:

a polarization super junction region comprising a first undoped GaN layer, an AlₓGa₁₋ₓN layer on the first undoped GaN layer and a second undoped GaN layer on the AlₓGa₁₋ₓN layer,

the Al composition x and the thickness t [nm] of the AlₓGa₁₋ₓN layer satisfying the following equation

t≧α(a)x^{β(a)}

where the thickness of the second undoped GaN layer is denoted as a [nm] (a is not smaller than 10 nm and not larger than 1000 nm),
α is expressed as

Log (α)=p₀+p₁ log (a)+p₂{log (a)}²

(p₀=7.3295, p₁=−3.5599, and p₂=0.6912) and β is expressed as

β=p′₀+p′₁ log (a)+p′₂{log (a)}²

(p′₀=−3.6509, p′₁=1.9445, and p′₂=−0.3793).

Furthermore, according to the invention, there is provided a mounted structure body, comprising:

a chip constituting a semiconductor element; and

a mount board on which the chip is flip chip mounted,

the semiconductor element being

a bidirectional field effect transistor, comprising:

a polarization super junction region and a p-electrode contact region which are provided separately each other,

the polarization super junction region, comprising a first undoped GaN layer, an AlₓGa₁₋ₓN layer on the first undoped GaN layer and an island-like second undoped GaN layer on the AlₓGa₁₋ₓN layer,

the Al composition x and the thickness t [nm] of the AlₓGa₁₋ₓN layer satisfying the following equation

t≧α(a)x^{β(a)}

where the thickness of the second undoped GaN layer is denoted as a [nm] (a is not smaller than 10 nm and not larger than 1000 nm),
α is expressed as

Log (α)=p₀+p₁ log (a)+p₂{log (a)}²

(p₀=7.3295, p₁=−3.5599, and p₂=0.6912) and β is expressed as

β=p′₀+p′₁ log (a)+p′₂{log (a)}²

(p′₀=−3.6509, p′₁=1.9445, and p′₂=−0.3793),

the polarization super junction region and the p-electrode contact region including the first undoped GaN layer, the AlₓGa₁₋ₓN layer and the second undoped GaN layer as common layers,

a first electrode and a second electrode constituting a source electrode or a drain electrode being provided on the AlₓGa₁₋ₓN layer so as to sandwich the second undoped GaN layer,

the p-electrode contact region, comprising:

a Mg-doped first p-type GaN layer on the second undoped GaN layer,

a Mg-doped second p-type GaN layer on the second undoped GaN layer, provided separately from the first p-type GaN layer,

a first p-type GaN contact layer which is doped with Mg heavier than the first p-type GaN layer, provided in contact with the first p-type GaN layer,

a second p-type GaN contact layer which is doped with Mg heavier than the second p-type GaN layer, provided in contact with the second p-type GaN layer,

a first p-electrode constituting a first gate electrode which is in ohmic contact with the first p-type GaN contact layer; and

a second p-electrode constituting a second gate electrode which is in ohmic contact with the second p-type GaN contact layer.

In the inventions of the electric equipment, the bidirectional field effect transistor and the mounted structure body, the explanation concerning the above invention of the semiconductor element comes into effect unless it is contrary to its character. As the mount board, a board having good thermal conductivity is used and selected from conventionally known boards as needed.

### Effect of the Invention

According to the invention, even though no p-type GaN layer is provided on the topmost surface of the polarization super junction region, it is possible to obtain an enough concentration of the two-dimensional hole gas formed in the second undoped GaN layer in the vicinity part of the hetero-interface between the AlₓGa₁₋ₓN layer and the second undoped GaN layer, for example, 1×10¹² cm⁻² or more at a non-operating time. And it is possible to realize high performance electric equipment using the semiconductor element or the bidirectional field effect transistor. In addition, by the mounted structure body in which the chip constituting the semiconductor element or the bidirectional field effect transistor is flip chip mounted on the mount board, it is possible to obtain excellent heat dissipation even when the semiconductor element or the bidirectional field effect transistor is formed on an insulating substrate.

### BRIEF DESCRIPTION OF THE DRAWINGS

FIG. 1 A cross-sectional view showing the basic structure of a polarization super junction GaN-based semiconductor element according to a first embodiment of the invention.

FIG. 2 A cross-sectional view showing the layer structure of samples which were used in experiments conducted to consider the polarization super junction GaN-based semiconductor element according to the first embodiment of the invention.

FIG. 3 A cross-sectional view showing a polarization super junction GaN-based field effect transistor which was made by using the layer structure shown in FIG. 2.

FIG. 4 A schematic view showing a drain current-drain voltage characteristic of the polarization super junction GaN-based field effect transistor shown in FIG. 3 where the remaining thickness of the undoped GaN layer 13 is 60 nm.

FIG. 5 A schematic view showing a drain current-gate voltage characteristic of the polarization super junction GaN-based field effect transistor shown in FIG. 3 where the remaining thickness of the undoped GaN layer 13 is 60 nm.

FIG. 6 A schematic view showing a drain leakage characteristic during the turn-off period of the polarization super junction GaN-based field effect transistor shown in FIG. 3 where the remaining thickness of the undoped GaN layer 13 is 60 nm.

FIG. 7 A plan view showing the sample for Hall measurement which was made in the experiment conducted to consider the polarization super junction GaN-based field effect transistor shown in FIG. 3.

FIG. 8A A cross-sectional view along the A-A′ line of the Hall measurement sample shown in FIG. 7.

FIG. 8B A cross-sectional view along the B-B′ line of the Hall measurement sample shown in FIG. 7.

FIG. 8C A cross-sectional view along the C-C′ line of the Hall measurement sample shown in FIG. 7.

FIG. 9 An energy band diagram of the polarization super junction region which was obtained by simulation carried out based on the one-dimensional model along the A-A′ line of FIG. 3.

FIG. 10 A schematic view showing profile of the 2DHG concentration and the 2DEG concentration of the polarization super junction region which was obtained by simulation.

FIG. 11 A schematic view showing the calculated value and the measured value of the 2DHG concentration for the remaining thickness of the undoped GaN layer 13.

FIG. 12 A schematic view showing the result of calculation of the 2DEG concentration where the remaining thickness of the undoped GaN layer 13 is 10 nm.

FIG. 13 A schematic view showing the result of calculation of the 2DHG concentration where the remaining thickness of the undoped GaN layer 13 is 10 nm.

FIG. 14 A schematic view showing the result of calculation of the 2DEG concentration where the remaining thickness of the undoped GaN layer 13 is 50 nm.

FIG. 15 A schematic view showing the result of calculation of the 2DHG concentration where the remaining thickness of the undoped GaN layer 13 is 50 nm.

FIG. 16 A schematic view showing the result of calculation of the 2DEG concentration where the remaining thickness of the undoped GaN layer 13 is 100 nm.

FIG. 17 A schematic view showing the result of calculation of the 2DHG concentration where the remaining thickness of the undoped GaN layer 13 is 100 nm.

FIG. 18 A schematic view showing the result of calculation of the 2DEG concentration where the remaining thickness of the undoped GaN layer 13 is 1000 nm.

FIG. 19 A schematic view showing the result of calculation of the 2DHG concentration where the remaining thickness of the undoped GaN layer 13 is 1000 nm.

FIG. 20 A schematic view showing the relation between the Al composition x and the thickness t of the AlₓGa₁₋ₓN layer where the remaining thickness of the undoped GaN layer 13 was changed.

FIG. 21 A schematic view showing the relation between Log(a) and Log(α) or β.

FIG. 22 A schematic view showing the relation between the Al composition x and the thickness t of the AlₓGa₁₋ₓN layer where the remaining thickness of the undoped GaN layer 13 was changed.

FIG. 23A A schematic view showing a polarization super junction GaN-based diode to which the polarization super junction GaN-based semiconductor element according to the first embodiment of the invention was applied.

FIG. 23B A cross-sectional view showing a polarization super junction GaN-based diode with the structure different from the polarization super junction GaN-based diode shown in FIG. 23A to which the polarization super junction GaN-based semiconductor element according to the first embodiment of the invention was applied.

FIG. 24 A cross-sectional view showing a polarization super junction GaN-based bidirectional field effect transistor according to the second embodiment of the invention.

FIG. 25 A circuit diagram showing a power circuit of a three-phase alternative current induction motor in which the polarization super junction GaN-based bidirectional filed effect transistor according to the second embodiment of the invention is used as a bidirectional switch of a matrix converter.

FIG. 26 A cross-sectional view showing a mounted structure body according to the third embodiment of the invention.

FIG. 27 A perspective view showing an example of the whole image of the mounted structure body according to the third embodiment of the invention.

FIG. 28 A cross-sectional view showing a mounted structure body according to the fourth embodiment of the invention.

FIG. 29 A perspective view showing an example of a chip constituting the mounted structure body according to the fourth embodiment of the invention.

FIG. 30 A cross-sectional view for explaining the method of flip chip mounting the chip shown in FIG. 29 on a submount substrate.

FIG. 31 A perspective view showing the result of a continuous energization experiment which was carried out by mounting the mounted structure body made by the method shown in FIG. 30 on a Peltier device.

FIG. 32 A cross-sectional view showing a mounted structure body according to the fifth embodiment of the invention.

FIG. 33 A schematic view showing the result of the switching characteristics of the polarization super junction GaN-based transistor which was measured by using a circuit in which a 300Ω resistor is connected as a load with the polarization super junction GaN-based field effect transistor with the structure shown in FIG. 3.

FIG. 34A A schematic view showing a cascode circuit using a normally-on field effect transistor to which the invention was applied.

FIG. 34B A schematic view showing a modified cascode circuit using the normally-on field effect transistor to which the invention was applied.

FIG. 34C A schematic view showing a modified cascode circuit using the normally-on field effect transistor to which the invention was applied.

FIG. 34D A schematic view showing a modified cascode circuit using the normally-on field effect transistor to which the invention was applied.

FIG. 34E A schematic view showing a modified cascode circuit using the normally-on field effect transistor to which the invention was applied.

FIG. 34F A schematic view showing a cascode circuit using the normally-on field effect transistor to which the invention was applied.

FIG. 34G A schematic view showing a modified cascode circuit using the normally-on field effect transistor to which the invention was applied.

### MODES FOR CARRYING OUT THE INVENTION

Modes for carrying out the invention (hereinafter referred as embodiments) will now be explained below.

### 1. The First Embodiment

The polarization super junction GaN-based semiconductor element according to the first embodiment is described. FIG. 1 shows the basic structure of the polarization super junction GaN-based semiconductor element.

As shown in FIG. 1, in the polarization super junction GaN-based semiconductor element, an undoped GaN layer 11, an AlₓGa₁₋ₓN layer 12 and an undoped GaN layer 13 are stacked in order on a base substrate (not illustrated) such as, for example, a C-plane sapphire substrate on which GaN-based semiconductor grows in C-plane orientation. The polarization super junction GaN-based semiconductor element comprises a polarization super junction region (intrinsic polarization super junction region) and a p-electrode contact region which are provided separately each other. The polarization super junction region comprises the undoped GaN layer 11, the AlₓGa₁₋ₓN layer 12 and the undoped GaN layer 13. More specifically, the polarization super junction region comprises only the undoped GaN layer 11, the AlₓGa₁₋ₓN layer 12 and the undoped GaN layer 13. As described above, an intermediate layer which does not deteriorate characteristics of the polarization super junction, for example, an undoped AlᵤGa₁₋ᵤN layer (0<u≦1, u>x) may be provided between the undoped GaN layer 11 and the AlₓGa₁₋ₓN layer 12 and/or between the undoped GaN layer 13 and the AlₓGa₁₋ₓN layer 12. The polarization super junction GaN-based semiconductor element is very different from the conventional polarization super junction GaN-based semiconductor element in that a p-type GaN layer, which was considered to be indispensable, is not provided on the undoped GaN layer 13 in the polarization super junction region, as described above. On the other hand, in the p-electrode contact region, further stacked on the undoped GaN layer 13 is a Mg-doped p-type GaN layer 14 and provided is a p-type GaN contact layer (hereinafter referred as “a p⁺-type GaN contact layer”) in which Mg is doped heavier than the p-type GaN layer 14 in contact with the p-type GaN layer 14. A p-electrode is electrically connected with the p⁺-type GaN contact layer. In FIG. 1, as an example, a case where the p⁺-type GaN contact layer 15 is stacked on the p-type GaN layer 14.

In the polarization super junction GaN-based semiconductor element, at a non-operating time, due to piezo polarization and spontaneous polarization, positive fixed charge is induced in the AlₓGa₁₋ₓN layer 12 in the vicinity part of a hetero-interface between the undoped GaN layer 11 and the AlₓGa₁₋ₓN layer 12 on the side of the base substrate, and negative fixed charge is induced in the AlₓGa₁₋ₓN layer 12 in the vicinity part of a hetero-interface between the AlₓGa₁₋ₓN layer 12 and the undoped GaN layer 13 on the opposite side of the base substrate. As a result, in the polarization super junction GaN-based semiconductor element, at a non-operating time, a two-dimensional hole gas (2DHG) 16 is formed in the undoped GaN layer 13 in the vicinity part of the hetero-interface between the AlₓGa₁₋ₓN layer 12 and the undoped GaN layer 13 and a two-dimensional electron gas (2DEG) 17 is formed in the undoped GaN layer 11 in the vicinity part of the hetero-interface between the undoped GaN layer 11 and the AlₓGa₁₋ₓN layer 12.

In the polarization super junction GaN-based semiconductor element, the Al composition x and the thickness t [nm] of the AlₓGa₁₋ₓN layer 12 constituting the polarization super junction region are determined so as to satisfy the following equation where the thickness of the undoped GaN layer 13 is denoted as a [nm] (a is not smaller than 10 nm and not larger than 1000 nm).

t≧α(a)x^{β(a)}

Here, α is expressed as

Log (α)=p₀+p₁ log (a)+p₂{log (a)}²

(p₀=7.3295, p₁=−3.5599, p₂=0.6912)
and β is expressed as

β=p′₀+p′₁ log (a)+p′₂{log (a)}²

(p′₀=−3.6509, p′₁=1.9445, p′₂=−0.3793).

Described below is the reason why the Al composition x and the thickness t [nm] of the AlₓGa₁₋ₓN layer 12 constituting the polarization super junction region are determined as described above.

### Experiment

For consideration, a polarization super junction GaN-based field effect transistor was made as follows.

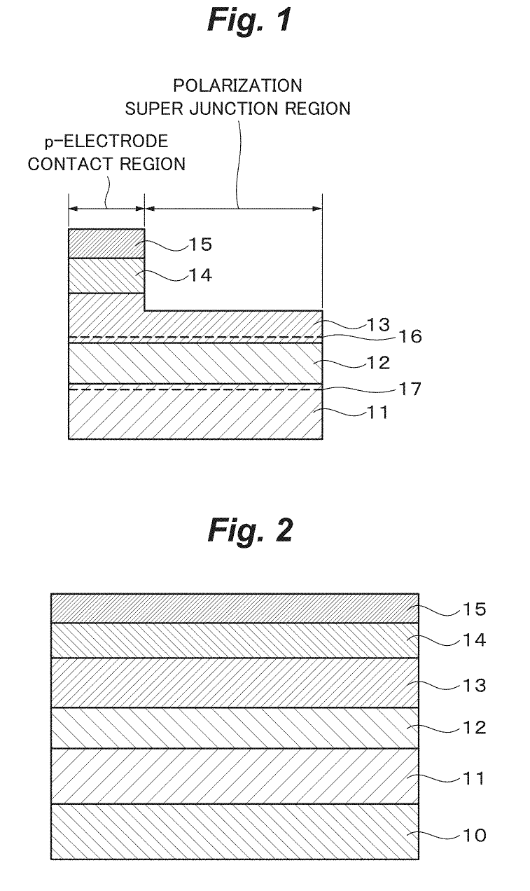

First, the layer structure shown in FIG. 2 was prepared. As shown in FIG. 2, stacked on a (0001)-plane, that is, C-plane sapphire substrate 10 was a low temperature growth (530° C.) GaN buffer layer (not illustrated) with a thickness of 30 nm by the conventionally known MOCVD (metal organic chemical vapor deposition) method using TMG (trimethyl gallium) as Ga source, TMA (trimethyl aluminium) as Al source, NH₃ (ammonia) as nitrogen source, N₂ gas and H₂ gas as carrier gas. Then the growth temperature was raised to 1100° C. and an undoped GaN layer 11 with a thickness of 1 μm, an AlₓGa₁₋ₓN layer 12 with a thickness of 47 nm and x=0.25, an undoped GaN layer 13 with a thickness of 80 nm, a Mg-doped p-type GaN layer 14 with a Mg concentration of 5.0×10¹⁹ cm⁻³ and a thickness of 50 nm and a Mg-doped p⁺-type GaN contact layer 15 with a Mg concentration of 2.0×10²⁰ cm⁻³ and a thickness of 3 nm were grown.

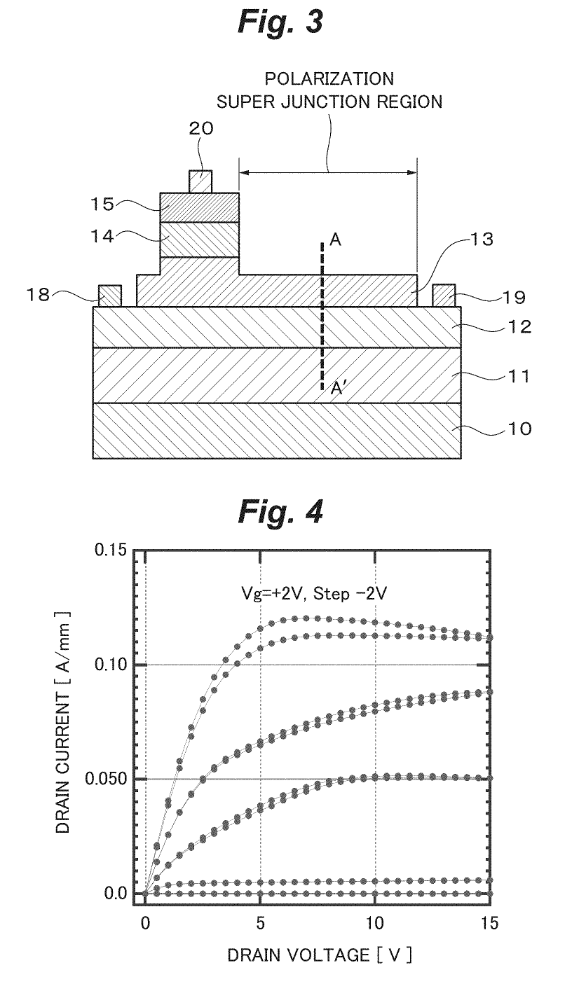

By using the layer structure shown in FIG. 2 the polarization super junction GaN-based field effect transistor shown in FIG. 3 was made. That is, first, a resist pattern (not illustrated) with a prescribed shape corresponding to the p-electrode contact region was formed on the p⁺-type GaN contact layer 15 with the standard photo lithographic technology, and then the p⁺-type GaN contact layer 15, the p-type GaN layer 14 and the undoped GaN layer 13 were etched in order by using the resist pattern as a mask. Etching was stopped in the depth midway in the thickness direction of the undoped GaN layer 13. In this way, a gate mesa comprising the upper part of the undoped GaN layer 13, the p-type GaN-layer 14 and the p⁺-type GaN contact layer 15 was formed. After removing the resist pattern which was used for etching, a SiO₂ film was formed on the whole surface of the substrate. A resist pattern (not illustrated) with a prescribed shape corresponding to the p-electrode contact region and the polarization super junction region was formed on the SiO₂ film by the standard photolithographic technology, and then the SiO₂ film was etched by using the resist pattern as a mask. As a result, only the surface of the p-electrode contact region and the polarization super junction region was covered with the SiO₂ film. After removing the resist pattern which was used for etching, the undoped GaN layer 13 was etched by using the SiO₂ film as a mask to expose partially the AlₓGa₁₋ₓN layer 12. Then the source electrode 18 and the drain electrode 19 were formed on the AlₓGa₁₋ₓN layer 12 which was exposed on both sides of the undoped GaN layer 13 patterned as described above such that they are in ohmic contact with the AlₓGa₁₋ₓN layer 12. More specifically, first a Ti/Al/Ni/Au layered film with a prescribed shape was formed as metal film for the source electrode 18 and the drain electrode 19, and then annealing process of about 750° C. and five minutes was carried out to make the Ti/Al/Ni/Au layered film ohmic contact with the AlₓGa₁₋ₓN layer 12. Then the p-electrode 20 serving as a gate electrode was formed on the p⁺-type GaN contact layer 15. More specifically, first a Ni/Au layered film with a prescribed shape was formed on the p⁺-type GaN contact layer 15 as a metal film for the p-electrode 20, and then annealing process of about 300° C. was carried out in nitrogen gas. Then a SiO₂ film was formed on the entire surface of the substrate as a protection film though its illustration was omitted. In this way, the polarization super junction GaN-based field effect transistor was made. In FIG. 3, the undoped GaN layer 11, the AlₓGa₁₋ₓN layer 12 and the undoped GaN layer 13 which are located between one lateral surface of the gate mesa part on the side of the drain electrode 19 and one lateral surface of the undoped GaN layer 13 on the side of the drain electrode 19 constitutes the polarization super junction region and its length Lₚₛⱼ is 15 μm.

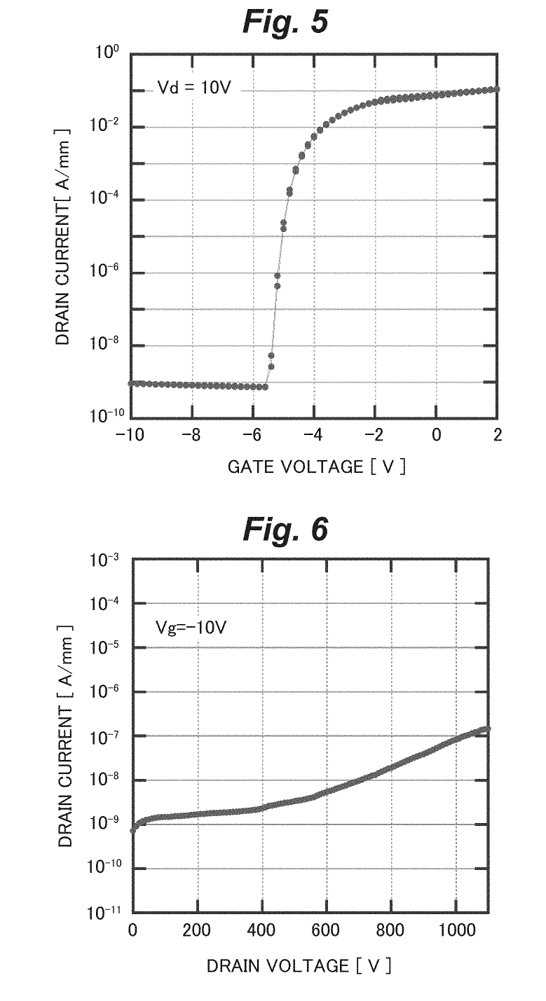

FIGS. 4 to 6 show results of measurement of static characteristics of the polarization super junction GaN-based field effect transistor where the thickness of the undoped GaN layer 13 (the remaining thickness of the undoped GaN layer 13 after etching when the thickness of the undoped GaN layer 13 before etching for forming the gate mesa part is used as the standard) in the state shown in FIG. 3 is set to 60 nm. Here, FIG. 4 shows the forward drain current (I_{d})-drain voltage (V_{d}) characteristic. FIG. 5 shows the drain current (I_{d})-gate voltage (V_{g}) characteristic (transmission characteristic), and FIG. 6 shows the I_{d}-V_{d} characteristic when V_{g}=−10V and the transistor was turned off. With respect to forward characteristics, the saturation current I_{dmax} was 120 mA/mm at V_{g}=+2V. The gate threshold voltage Vₜₕ was about −5.0 V. From FIG. 6, the drain current I_{d} when the transistor was turned off was in 10⁻⁷ A/mm at V_{d}˜1100V. Such an excellent voltage resistance characteristic of the transistor is obtained because the polarization super junction (PSJ) effect results, and a two-dimensional hole gas (2DHG) with a high effective concentration is formed in the undoped GaN layer 13 in the vicinity part of the hetero-interface between the AlₓGa₁₋ₓN layer 12 and the undoped GaN layer 13 as described later. It will be described later that a high concentration 2DHG can be obtained even though no p-type GaN layer is provided on the topmost surface, in other words, on the undoped GaN layer 13.

A depth distribution of Mg was measured by secondary ion mass spectroscopy (SIMS). According to the result of measurement, it was confirmed that the Mg concentration at a depth of 20 nm under the p-type GaN layer, in other words, the Mg concentration of the undoped GaN layer 13 at a depth of 20 nm from the interface between the p-type GaN layer 14 and the undoped GaN layer 13 was 1.0×10¹⁶ cm⁻³ or under and near to SIMS detection limit. As a result, Mg does not exist at a depth of 20 nm under the p-type GaN layer.

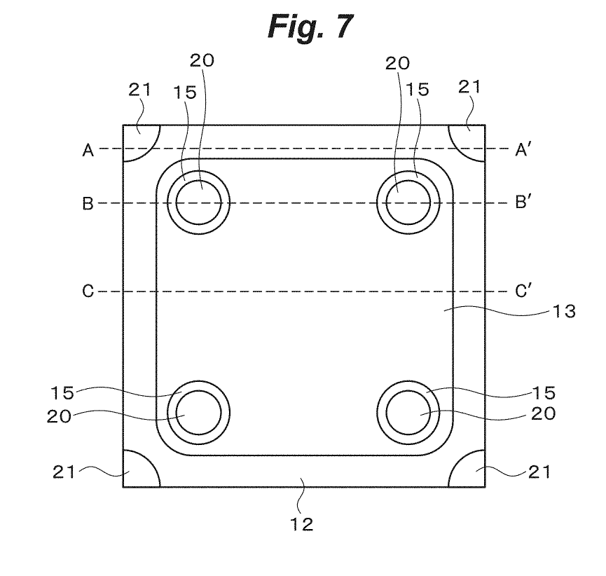

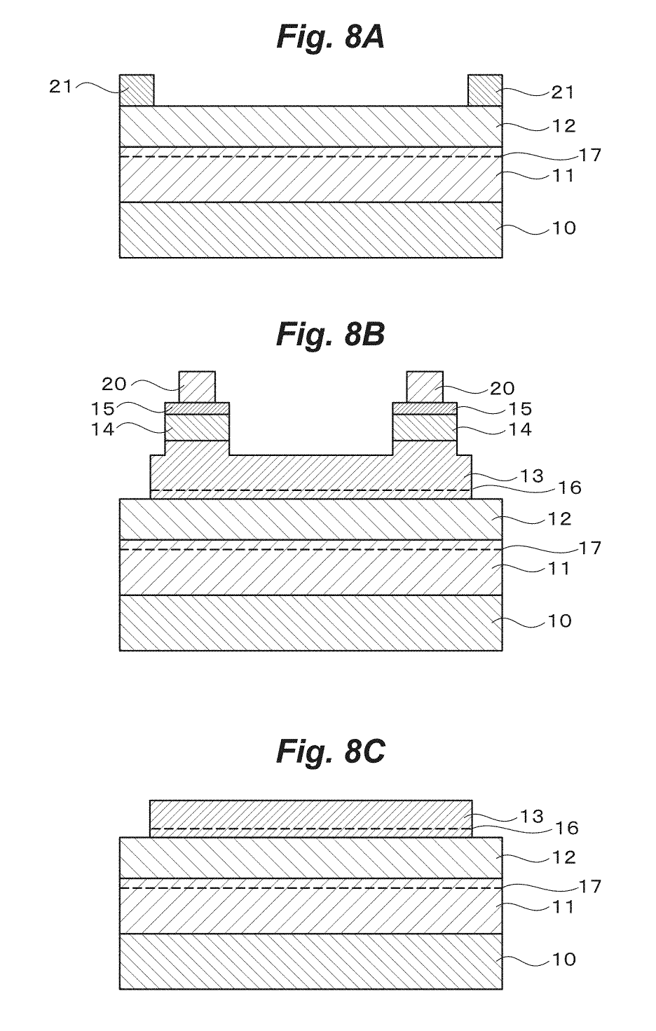

In order to measure concentrations of the two-dimensional hole gas (2DHG) and the two-dimensional electron gas (2DEG) (hereinafter, a concentration with a unit of cm⁻² denotes a sheet concentration and a concentration with a unit of cm⁻³ denotes a volume concentration), a Hall element shown in FIG. 7, FIG. 8A, FIG. 8B, and FIG. 8C was made by using steps for making a transistor. Here, FIG. 7 is a plan view of the Hall element and FIG. 8A, FIG. 8B and FIG. 8C are cross-sectional views along the A-A′ line, the B-B′ line and the C-C′ line of FIG. 7, respectively. A polarization super junction region of the undoped GaN layer 13 and an electrode region of the AlₓGa₁₋ₓN layer 12 were formed. Four p-electrodes 20 formed on the p⁺-type GaN contact layer 15 on four corners of undoped GaN layer 13 were used to measure the 2DHG concentration. Four electrodes 21 formed on four corners of the AlₓGa₁₋ₓN layer 12 were used to measure the 2DEG concentration.

The result of measurement is shown in Table 1. The remaining thickness of the undoped GaN layer 13 of the sample No. 1 was 60 nm. The remaining thickness of the undoped GaN layer 13 of the sample No. 2 was 40 nm. The remaining thickness of the undoped GaN layer 13 of the sample No. 3 was 5 nm. It is understood from Table 1 that in the sample No. 1 and the sample No. 2, the 2DHG is induced and accumulated in the undoped GaN layer 13 in the vicinity part of the hetero-interface between the AlₓGa₁₋ₓN layer 12 and the undoped GaN layer 13 and the 2DEG is induced and accumulated in the undoped GaN layer 11 in the vicinity part of the hetero-interface between the AlₓGa₁₋ₓN layer 12 and the undoped GaN layer 11 by the polarization super junction (PSJ) effect. With respect to the sample No. 3, the Hall voltage for holes was not generated and measurement was impossible.

TABLE 1

| | No. 1 | No. 2 | No. 3 |
|---|---|---|---|
| | REMAINING | REMAINING | REMAINING |
| | THICKNESS | THICKNESS | THICKNESS |
| | OF UNDOPED | OF UNDOPED | OF UNDOPED |
| SAMPLE | GaN LAYER = 60 nm | GaN LAYER = 40 nm | GaN LAYER = 5 nm |
| 2DHG CONCENTRATION | 7.08 × 10¹² | 6.60 × 10¹² | UNMEASURABLE |
| [cm⁻²] | | | |
| HOLE MOBILITY | 6.05 | 5.2 | UNMEASURABLE |
| [cm²/Vs] | | | |
| 2DEG CONCENTRATION | 6.78 × 10¹² | 6.43 × 10¹² | 8.15 × 10¹² |
| [cm⁻²] | | | |
| ELECTRON MOBILITY | 863.5 | 871.0 | 880.6 |
| [cm²/Vs] | | | |

Because the 2DHG concentration of the sample No. 2 is smaller than the 2DHG concentration of the sample No. 1, it was shown that the 2DHG concentration depends on the thickness of the undoped GaN layer 13. This results from the surface pinning effect of the undoped GaN layer 13 and the existence of donor type levels (electron emission type) or hole trapping levels. The existence of the 2DHG is indispensable in the polarization super junction element. Therefore, it is necessary to examine quantitatively the relation between the amount of 2DHG generated and the constitution of the AlₓGa₁₋ₓN layer 12 and the undoped GaN layer 13.

### [Comparison Between Model Calculation and the 2DHG Concentration Measured]

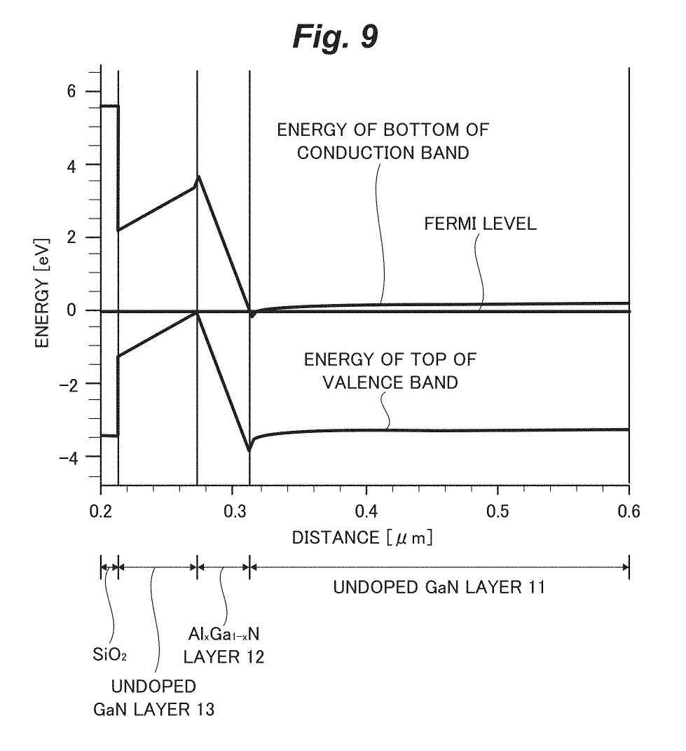

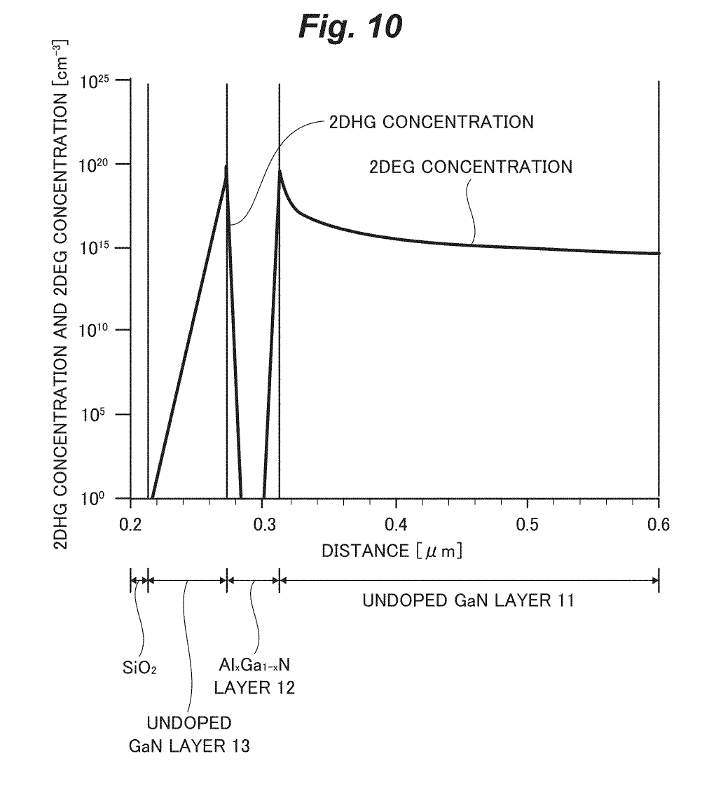

In order to derive the relation between the layer structure of the polarization super junction region consisting of the undoped GaN layer 13/the AlₓGa₁₋ₓN layer 12/the undoped GaN layer 11 and the 2DHG concentration, the band calculations were carried out. That is, the calculations were carried out for a one-dimensional model along the A-A′ line of the polarization super junction region shown in FIG. 3. Atlas of Silvaco, Inc. was used as a simulator software. FIG. 9 shows the band diagram calculated of the undoped GaN layer 13 (thickness 60 nm)/the AlₓGa₁₋ₓN layer 12 (x=0.24, thickness 47 nm)/the undoped GaN layer 11 in an equilibrium state. FIG. 10 shows the concentration profile of the 2DHG and the 2DEG. Band bending occurs by the positive fixed charge (polarization charge) induced in the AlₓGa₁₋ₓN layer 12 in the vicinity part of the hetero-interface between the undoped GaN layer 11 and the AlₓGa₁₋ₓN layer 12 and the negative fixed charge (polarization charge) induced in the AlₓGa₁₋ₓN layer 12 in the vicinity part of the hetero-interface between the AlₓGa₁₋ₓN layerl2 and the undoped GaN layer 13. As a result, the 2DHG is induced in the undoped GaN layer 13 in the vicinity part of the hetero-interface between the AlₓGa₁₋ₓN layer 12 and the undoped GaN layer 13 and the 2DEG is induced in the undoped GaN layer 11 in the vicinity part of the hetero-interface between the AlₓGa₁₋ₓN layer 12 and the undoped GaN layer 11. The peak concentration of the 2DHG is 1×10²⁰ cm⁻³ and the peak concentration of the 2DEG is 6×10⁷ cm⁻³ and both concentrations decrease exponentially with the distance from the hetero-interface. The 2DEG concentration shows a constant value, 1×10¹⁵ cm⁻³ in the deep position of the undoped GaN layer 11, because the undope level of the undoped GaN layer 11 was set to 1×10¹⁵ cm⁻³ for the sake of calculation. This will not affect discussions below.

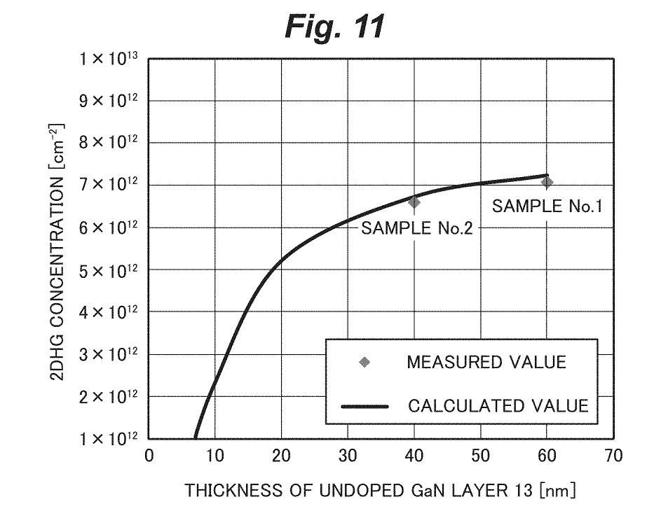

The integral value of the carrier concentration in the depth direction shows the sheet carrier concentration. FIG. 11 shows the 2DEG concentration as the sheet carrier concentration. In FIG. 11, the thickness of the undoped GaN layer 13 is shown in the abscissa and the 2DHG concentration is shown in the ordinate. The 2DHG concentrations of the sample No. 1 and the sample No. 2 are plotted in FIG. 11.

It is understood from FIG. 11 that the result of simulation (calculated values by the band calculation) reproduces the measured values well and parameters of physical properties of matter of the model used in the simulation (its details are not shown) satisfy a necessary condition for the purpose of exploring the practical polarization super junction structure.

As shown in FIG. 11, according to the simulation, the 2DHG concentration is calculated to be about 1×10¹² cm⁻² for the thickness of 7 nm of the undoped GaN layer 13. In this region, the 2DHG concentration drastically decreases as the thickness of the undoped GaN layer 13 decreases and is 0.6×10¹² cm⁻² for the thickness of 5 nm. Measurement of the corresponding sample was impossible. Its reason is as follows. Suppose that the hole mobility is about 3 cm⁻²/Vs. When the 2DHG concentration of the sample is 0.6×10¹² cm⁻² as described above, the sheet resistance is 1/neμ=1/(0.6×10¹²×1.6×10¹⁹×3)˜3.5MΩ/□. It is difficult to carry out Hall measurement for the sample with such a sheet resistance. Here, n is the sheet concentration, e is the absolute value of the charge of an electron and μ is the hole mobility. It is possible that the etching damage caused during etching for forming a gate mesa reaches to the hetero-interface between the undoped GaN layer 13 and the AlₓGa₁₋ₓN layer 12 to decrease further the 2DEG concentration. This may be another reason for a problem of impossible measurement. This shows that there is a limit of the remaining thickness of the undoped GaN layer 13 in an actual device fabrication and the thickness of 5 nm is too small. In addition, even if there is no effect of the surface damage, there is still a limit of the remaining thickness of the undoped GaN layer 13, taking accuracy of etching during device fabrication into consideration, and it is considered that the thickness of 10 nm or more is actually needed.

When the 2DHG concentration of the device is ×10 cm⁻², it is considered that the device operates as a polarization super junction device in principle. However, when the 2DHG concentration is too low, there is a fear of a problem of generation of the peak electric field at the gate edge, which is observed in ordinary HEMT devices. In order to obtain the effect as the polarization super junction device effectively, the 2DHG concentration is needed to be 1×10¹² cm⁻² or more and preferably 2×10¹² cm⁻² or more. The thickness of the undoped GaN layer 13 is desired to be large because the 2DHG concentration becomes larger as the thickness becomes larger. However, when the thickness of the undoped GaN layer 13 is too large, it becomes impossible to fabricate the device. Therefore, the thickness of the undoped GaN layer 13 is desired to be 1000 nm or less.

[Calculation to Investigate the Relation Between the Al Composition x and the Thickness t of the AlₓGa₁₋ₓN Layer 12 and the 2DHG Concentration in the Polarization Super Junction Structure Consisting of the Undoped GaN Layer 13/the AlₓGa₁₋ₓN Layer 12/the Undoped GaN Layer 11]

The thickness a of the undoped GaN layer 13 was used as parameters and set to a=10 nm, 50 nm, 100 nm and 1000 nm, respectively. The 2DEG concentration and the 2DHG concentration were calculated while the Al composition x and the thickness t of the AlₓGa₁₋ₓN layer 12 were varied. Here, x was varied by 0.05 in a range of 0.05˜0.5 (5˜50%) and t was varied by 1 nm in a range of 5˜10 nm and by 5 nm in a range of 10˜100 nm. And calculation was carried out by combining each value of x and each value of t like a matrix.

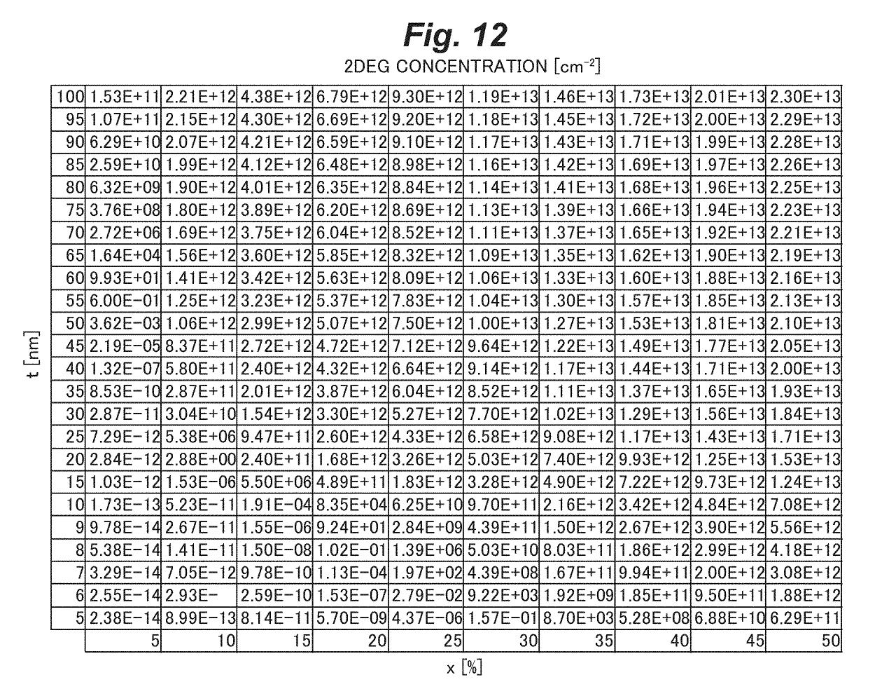

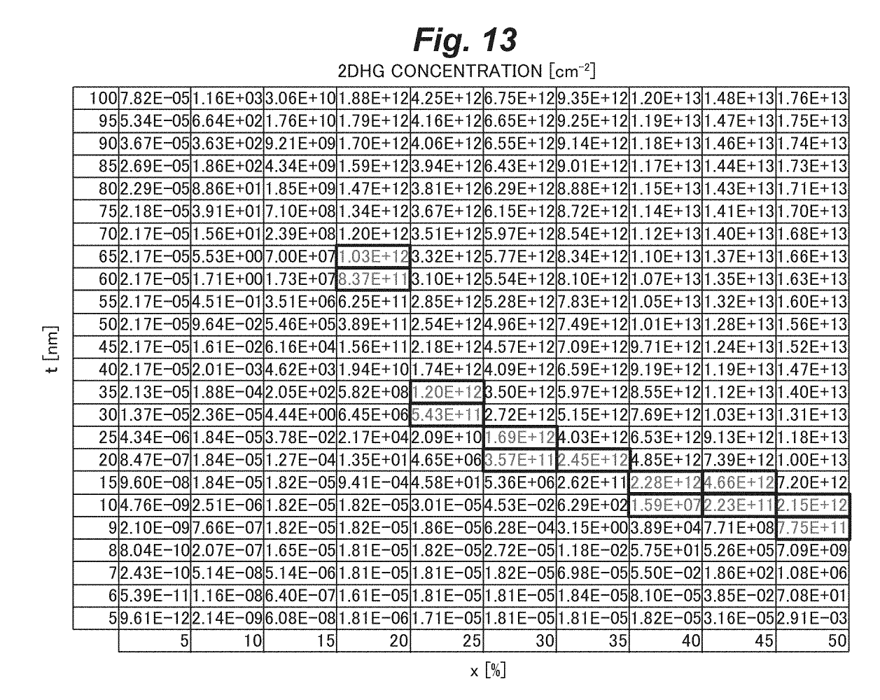

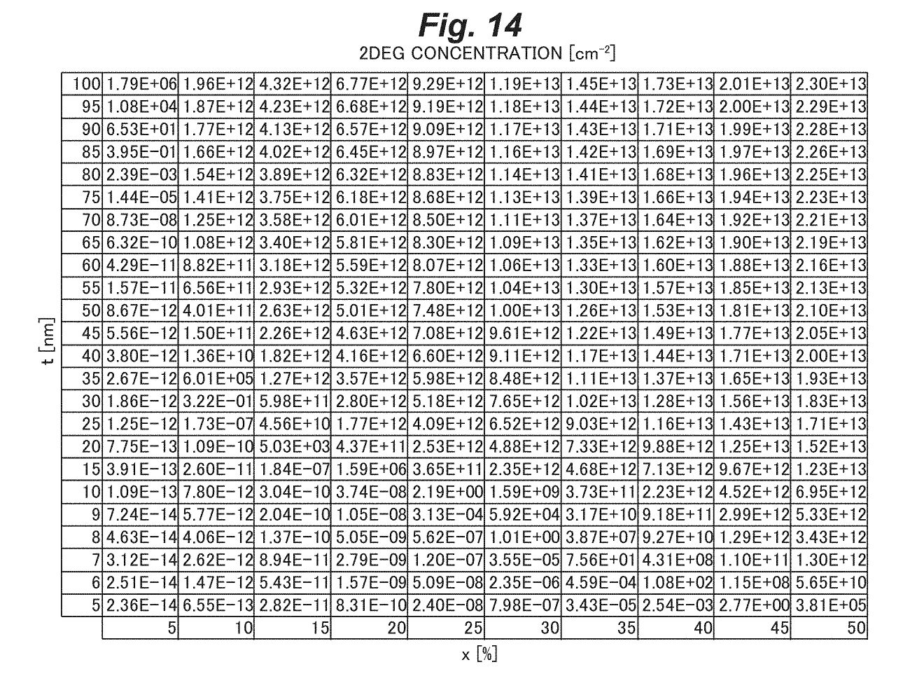

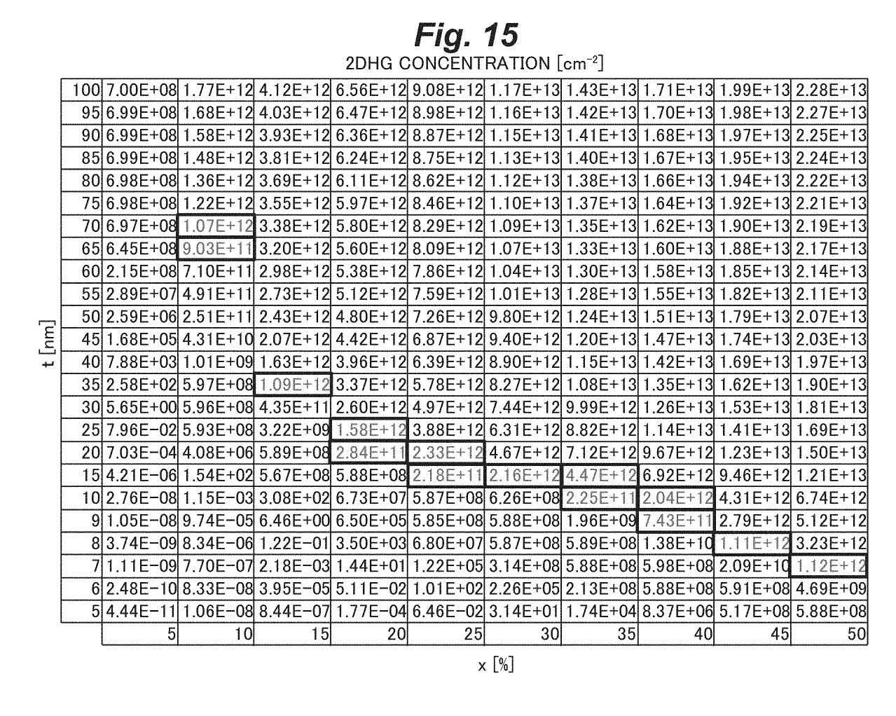

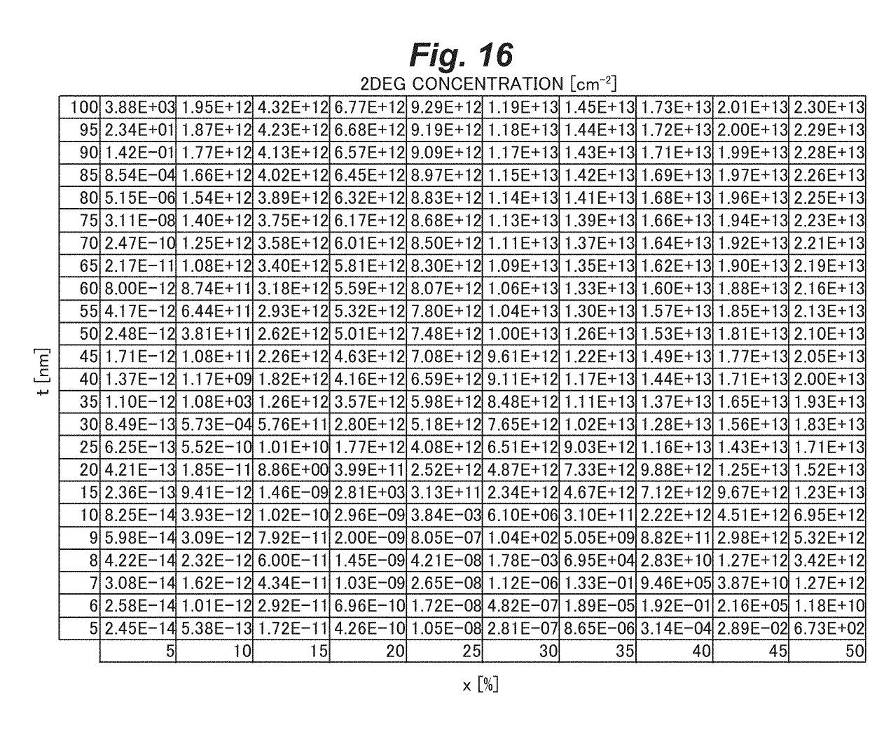

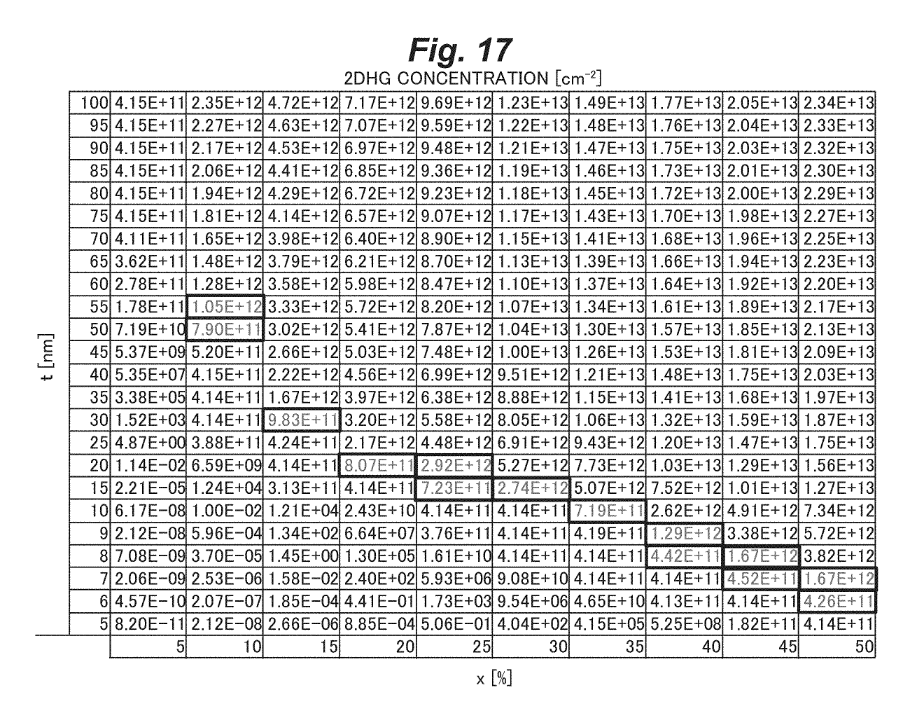

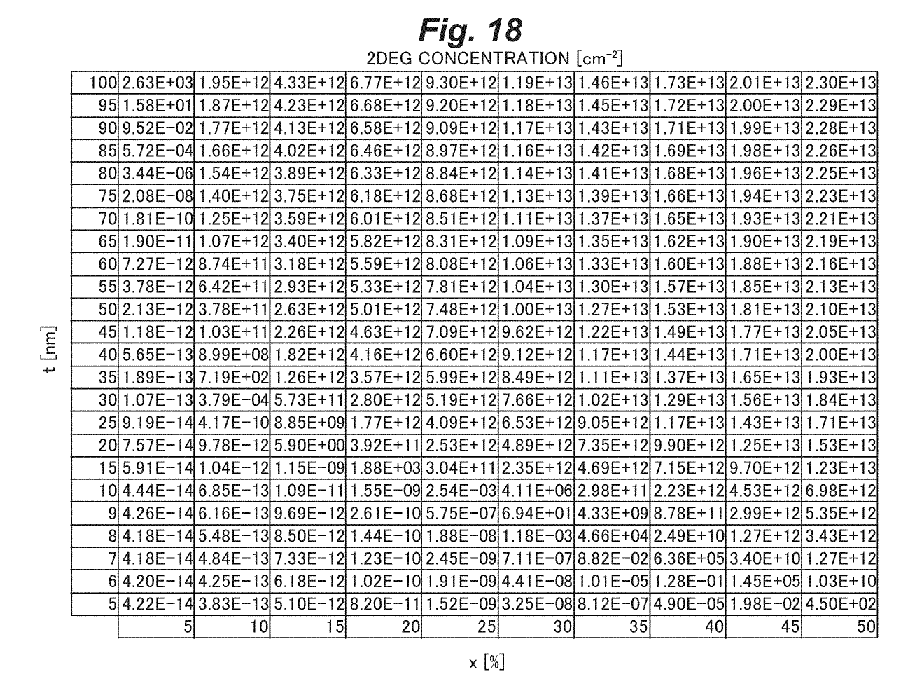

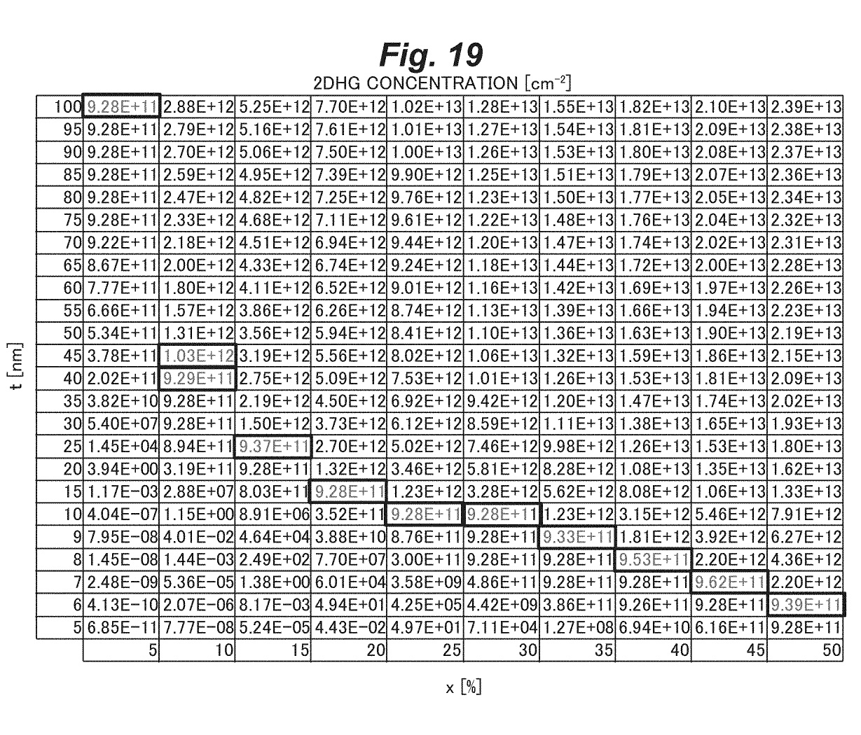

FIG. 12 and FIG. 13 show tables of calculated values of the 2DEG concentration and the 2DHG concentration for the Al composition x and the thickness t (nm) of the AlₓGa₁₋ₓN layer 12 when the thickness a of the undoped GaN layer 13 is 10 nm. Needless to say, in FIG. 12, for example, “1.53E+11” means 1.53×10¹¹ (similar in FIG. 13 and FIG. 14˜FIG. 19 described below). FIG. 14 and FIG. 15 show similar tables of calculated values of the 2DEG concentration and the 2DHG concentration when the thickness a of the undoped GaN layer 13 is 50 nm. FIG. 16 and FIG. 17 show similar tables of calculated value of the 2DEG concentration and the 2DHG concentration when the thickness a of the undoped GaN layer 13 is 100 nm. FIG. 18 and FIG. 19 show similar tables of calculated values of the 2DEG concentration and the 2DHG concentration when the thickness a of the undoped GaN layer 13 is 1000 nm.

Inspecting the state of distribution of the 2DHG concentration shown in FIG. 13, FIG. 15, FIG. 17 and FIG. 19, it is understood that as x becomes large and t becomes large, the 2DHG concentration increases. From FIG. 13, FIG. 15, FIG. 17 and FIG. 19, values of x and t giving the concentration of 1.00×10¹² cm⁻² are extracted. Here, in FIG. 13, FIG. 15, FIG. 17 and FIG. 19, cells near the 2DHG concentration of 1.00×10¹² cm⁻² are surrounded by a thick line. Since the values of cells in tables are not exactly 1.00×10¹² cm⁻², values of x and t were obtained from the values of the cells in front of and behind the cell in proportional distribution.

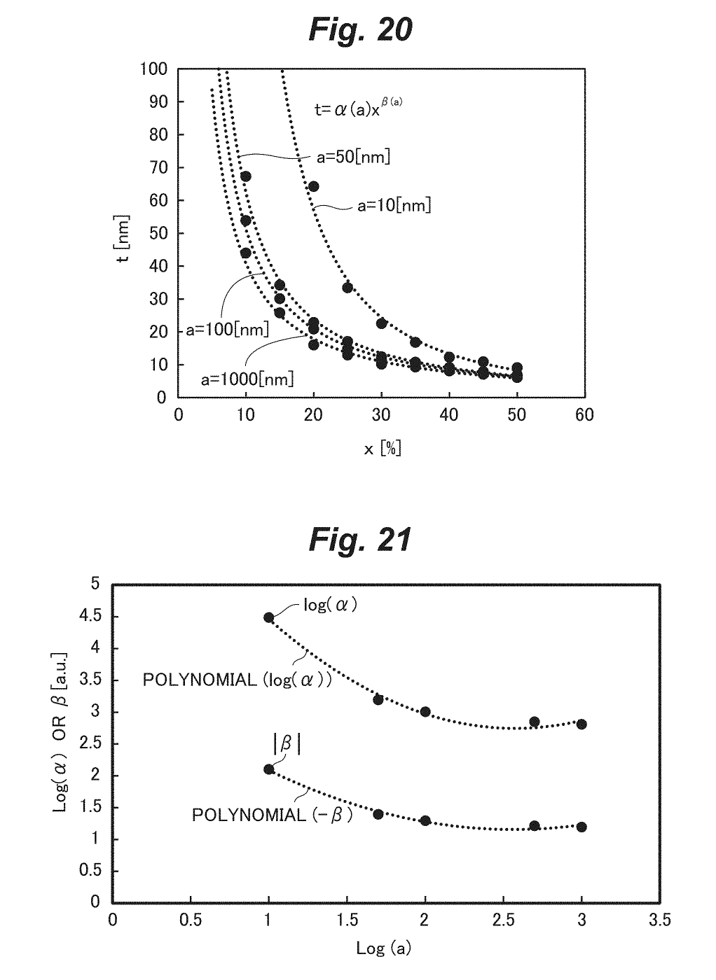

FIG. 20 shows the (x, t) coordinate plane in which points of (x, t) showing values of the 2DHG concentration=1.00×10¹² cm⁻², which were picked up from FIG. 13, FIG. 15, FIG. 17 and FIG. 19, were plotted. In FIG. 20, the region on the right side (or the upper side) of respective points is the area where the 2DHG concentration ≧1.00×10¹² cm⁻². From this, it can be understood that when the thickness a of the undoped GaN layer 13 is small, the Al composition x and the thickness t of the AlₓGa₁₋ₓN layer 12 to obtain the 2DHG concentration of 1×10¹² cm⁻² or more are large. It was made clear that as the thickness a of the undoped GaN layer 13 increases to 100 nm or more, the change of the 2DHG concentration saturates. This is understood that the band shape near the hetero-interface between the undoped GaN layer 13 and the AlₓGa₁₋ₓN layer 12 does not change even if the thickness a of the undoped GaN layer 13 increases.

Obtained now is an approximate equation expressing values of coordinate (x, t) in respective series of the thickness a of the undoped GaN layer 13 shown in FIG. 20. The approximate equation expresses the approximate curve giving the 2DHG concentration of 1×10¹² cm⁻². The approximate equation is expressed as follows.

t=α(a)x^{β(a)} (1)

Here, α and β are functions of the thickness a of the undoped GaN layer 13.

The curve shown by the dotted line in FIG. 20 fits to the approximate equation and values of the parameters α and β of the equation (1) are as shown in Table 2.

TABLE 2

| a [nm] | α | β |
|---|---|---|
| 10 | 30689 | −2.1 |
| 50 | 1555 | −1.396 |
| 100 | 1011 | −1.295 |
| 1000 | 641 | −1.196 |

As shown in FIG. 21, α and β shown in Table 2 are plotted for the thickness a [nm] of the undoped GaN layer 13. In FIG. 21, the vertical axis corresponds to log (α) or β and the horizontal axis corresponds to log (a) of the thickness a of the undoped GaN layer 13.

As an approximate function for the above values, the second order polynomial

Y=p₀+p₁X+p₂X² (2)

was adopted. Here, Y=Log (α) or β, X=log (a). That is,

Log (α)=p₀+p₁ log (a)+p₂{log (a)}² (3)

β=p′₀+p′₁ log (a)+p′₂{log (a)}² (4)

In the equation (4), p′₀, p′₁, p′₂ were used instead of p₀, p₁, p₂.

Coefficients obtained by the polynomial fitting are shown in Table 3.

TABLE 3

| | p₀ or p′₀ | p₁ or p′₁ | p₂ or p′₂ |
|---|---|---|---|
| Log(α) | 7.3295 | −3.5599 | 0.6912 |
| β | −3.6509 | 1.9445 | −0.3793 |

From the above discussion, it is concluded as follows. That is, from (p₀, p₁, p₂) and (p′, p′₁, p′₂), α and β are given by the equation (3) and the equation (4) for any thickness aof the undoped GaN layer 13 in the range from 10 nm to 1000 nm. Therefore, with the equation (1), the thickness t of the AlₓGa₁₋ₓN layer 12 giving the 2DHG concentration=1×10¹² cm⁻² for the Al composition x of the AlₓGa₁₋ₓN layer 12.

That is, the conditions of the Al composition x and the thickness t of the AlₓGa₁₋ₓN layer 12 giving the 2DHG concentration of 1×10¹² cm⁻² or more are expressed as follows for the thickness a of the undoped GaN layer 13 in the range from 10 nm to 100 nm.

t≧α(a)x^{β(a)} (5)

Here, α is given by the equation (3) and its coefficients are expressed as

p₀=7.3295, p₁=−3.5597, p₂=0.6912 (6)

and β is expressed by the equation (4) and its coefficients are expressed as

p′₀=−3.6509, p′₁=1.9445, p′₂=−0.3793 (7)

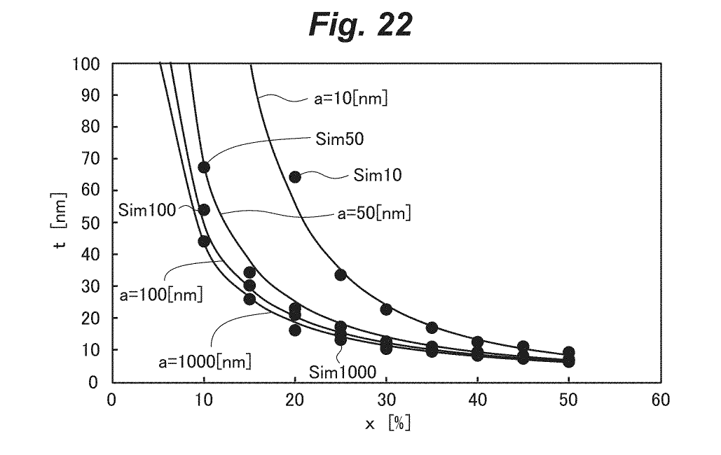

The validity of the conclusion is now verified. FIG. 22 shows the result of calculation carried out by using the approximate equation (1) for fitting, the polynomials (3) and (4) for deriving its coefficients α and β and the coefficients (6) and (7). More specifically, FIG. 22 shows the result of calculation of x and t for which the 2DHG concentration becomes 1×10¹² cm⁻² for the thickness a of the undoped GaN layer 13 of 10 nm, 50 nm, 100 nm and 1000 nm, respectively, that is, the isoconcentration curve of x and t. On the other hand, marks (expressed as Sim10, Sim50, Sim100 and Sim 1000) in FIG. 22 are results obtained by the band calculation, which are consistent with measured vales. From FIG. 22, it is understood that the approximate equation fits the band calculation data very well and the validity of the approximate equation and the coefficients was verified.

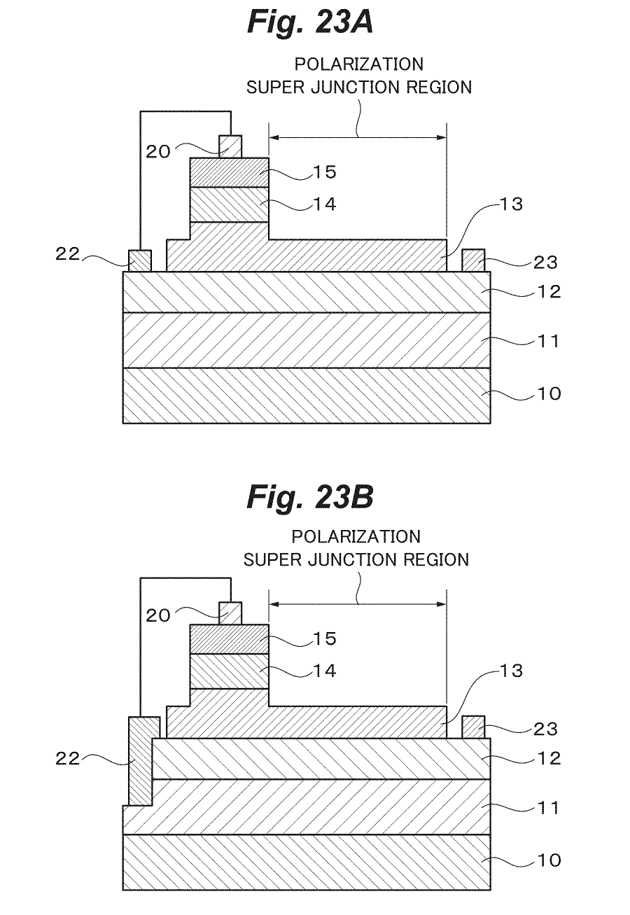

The polarization super junction GaN-based semiconductor element can be applied not only to the field effect transistor shown in FIG. 3 but also to a diode. FIG. 23A shows an example of a polarization super junction GaN-based diode. As shown in FIG. 23A, the polarization super junction GaN-based diode has nearly the same structure as that of the polarization super junction GaN-based field effect transistor shown in FIG. 3, and an anode electrode 22 is formed instead of the source electrode 18, a cathode electrode 23 is formed instead of the drain electrode 19 and the anode electrode 22 and the p-electrode 20 are mutually electrically connected. Here, the anode electrode 22 is formed to make possible Schottky contact with the AlₓGa₁₋ₓN layer 12 and the cathode electrode 23 is formed to make possible ohmic contact with the AlₓGa₁₋ₓN layer 12. The anode electrode 22 is made of, for example, a Ni/Au two-layer film and the cathode electrode 23 is made of, for example, a Ti/Al/Au three-layer film. Other than the above of the polarization super junction GaN-based diode is the same as the polarization super junction GaN-based field effect transistor shown in FIG. 3. FIG. 23B shows another example of the polarization super junction GaN-based diode. As shown in FIG. 23B, in the polarization super junction GaN-based diode, an edge portion of the undoped GaN layer 11 and the AlₓGa₁₋ₓN layer 12 are removed by etching to the middle depth of the undoped GaN layer 11 in the thickness direction to form a step, and the anode electrode 22 is formed so that it comes in contact with the base and the side of the step and further extends on the AlₓGa₁₋ₓN layer 12. In this case, the anode electrode 22 is in Schottky contact with the 2DEG 17 formed in the undoped GaN layer 11 in the vicinity part of the hetero-interface between the AlₓGa₁₋ₓN layer 12 and the undoped GaN layer 11. The height of the Schottky barrier of the Schottky junction between the anode electrode 22 and the 2DEG 17 is smaller than the height of the Schottky barrier of the Schottky junction between the anode electrode 22 and the AlₓGa₁₋ₓN layer 12 in the polarization super junction GaN-based diode shown in FIG. 23A. Other than the above of the polarization super junction GaN-based diode is the same as the polarization super junction GaN-based diode shown in FIG. 23A.

According to the first embodiment, it is possible to realize a polarization super junction GaN-based semiconductor element which can obtain the 2DHG 16 with the sufficient concentration without providing the p-type GaN layer, which was considered to be indispensable in the conventional polarization super junction GaN-based semiconductor element proposed in patent literature 3 and non-patent literature 3. In addition, it is possible to realize a polarization super junction GaN-based semiconductor element which can easily overcome the tradeoff relation between the high voltage resistance and high speed in the semiconductor element using a polarization super junction, realize both the high voltage resistance and elimination of the occurrence of current collapse during switching and operate in high speed and further the loss is low.

### 2. The Second Embodiment

The polarization super junction GaN-based bidirectional field effect transistor according to the second embodiment is described.

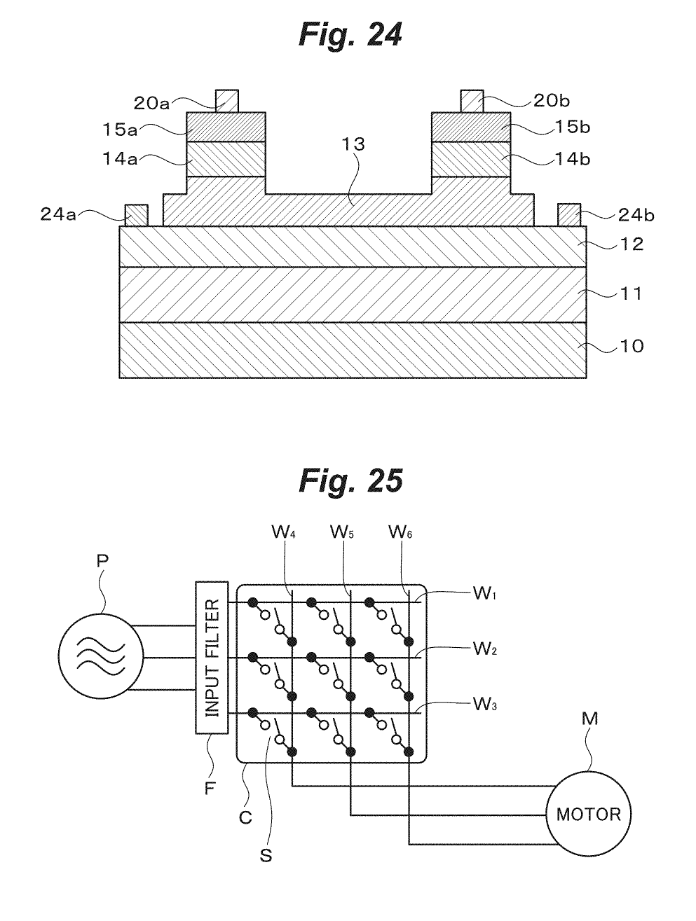

FIG. 24 shows the polarization super junction GaN-based bidirectional field effect transistor. As shown in FIG. 24, in the polarization super junction GaN-based bidirectional field effect transistor, the undoped GaN layer 11, the AlₓGa₁₋ₓN layer 12 and the undoped GaN layer 13 are stacked on the C-plane sapphire substrate 10 in order, as the same as the polarization super junction GaN-based field effect transistor shown in FIG. 3. The undoped GaN layer 13 has an island shape. The mesa consisting of the p-type GaN layer 14a and the p⁺-type GaN contact layer 15a thereon and the mesa consisting of the p-type GaN layer 14b and the p⁺-type GaN contact layer 15b thereon are formed separately on both ends of the undoped GaN layer 13. A first electrode 24a and a second electrode 24b constituting a source electrode and a drain electrode are formed separately each other on the AlₓGa₁₋ₓN layer 12 so as to sandwich the undoped GaN layer 13. A p-electrode 20a used as a gate electrode is formed on the p⁺-type GaN contact layer 15a and a p-electrode 20b used as a gate electrode is formed on the p⁺-type GaN contact layer 15b. The first electrode 24a, the second electrode 24b, the p-type GaN layers 14a, 14b, the p⁺-type GaN contact layers 15a, 15b and the p-electrodes 20a, 20b are formed symmetrically with respect to the undoped GaN layer 13.

The polarization super junction GaN-based bidirectional field effect transistor can turn on or off both forward and reverse voltage for AC voltage input by signal voltages (switch signals) applied to the p-electrodes 20a, 20b that are used as gate electrodes. In this case, depending on polarity of AC voltage input the first electrode 24a or the second electrode 24b act as the source electrode or the drain electrode.

The polarization super junction GaN-based bidirectional field effect transistor is suitable for a bidirectional switch of a matrix converter. An example is shown in FIG. 25. FIG. 25 shows a power supply circuit of a three phase AC induction motor M using the matrix converter. As shown in FIG. 25, in the matrix converter C, at each intersection of transverse wires W₁, W₂ and W₃ and vertical wires W₄, W₅ and W₆, the bidirectional switch S that connects the transverse wire and the vertical wire that intersects at each intersection is formed as a matrix. Each phase voltage of three phase AC power supply P is input to the wires W₁, W₂ and W₃ through an input filter F. The wires W₄, W₅ and W₆ are connected with the three phase AC induction motor M. As the bidirectional switch S, the polarization super junction GaN-based bidirectional field effect transistor shown in FIG. 24 is used.

In the power supply circuit shown in FIG. 25, by turning on or off the bidirectional switch S of the matrix converter C, each phase voltage of the three phase AC input to the wires W₁, W₂ and W₃ is directly cut like a thin rectangle by pulse width modulation (PWM), AC voltage of arbitrary voltage and frequency thus obtained is output to the wires W₄, W₅ and W₆ and the three phase AC induction motor M is driven.

The polarization super junction GaN-based bidirectional field effect transistor is also suitable for the bidirectional switch of a multi-level inverter. The multi-level inverter is effective, for example, for improving the power conversion efficiency of a power conversion system (for example, see Fujijiho, Vol. 83, No. 6 2010. pp. 362-365).

The polarization super junction GaN-based bidirectional field effect transistor according to the second embodiment can reduce a rising time when a switch signal is input to the gate electrode and achieve high speed operation as compared with a polarization super junction GaN-based field effect transistor that is not constructed as bidirectional, for example, the polarization super junction GaN-based field effect transistor shown in FIG. 3. Therefore, by using the polarization super junction GaN-based bidirectional field effect transistor as the bidirectional switch S of the matrix converter shown in FIG. 25, it is possible to switch the bidirectional switch S at a high speed and achieve high speed operation of the matrix converter C. With this, it is possible to realize a high performance matrix converter C and realize a high performance AC power supply circuit by using the matrix converter C. Similarly, it is possible to realize a high performance multi-level inverter and realize a high efficiency power conversion system by using the multi-level inverter.

### 3. The Third Embodiment

In the third embodiment, described is the mounted structure body in which a chip constituting the polarization super junction GaN-based field effect transistor or the polarization super junction GaN-based bidirectional field effect transistor according to any one of the first and the second embodiments is flip chip mounted on a mount board.

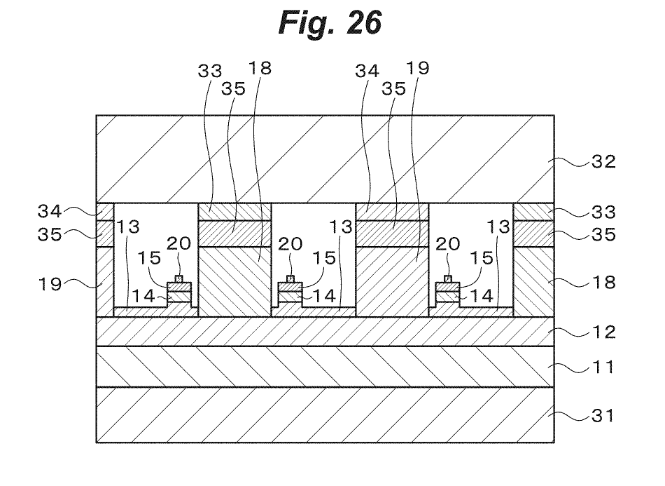

In the flip chip technology, to aim at the heat radiation of the chip, it is necessary to join the chip to the submount substrate in an area of the chip near the heating part. In a lateral high current field effect transistor, usually, all of the gate electrode, the source electrode and the drain electrode have an interdigital structure. Here, it is desired that the submount substrate is directly and thermally in contact with ohmic electrodes, that is, the source electrode and the drain electrode of the teeth of the interdigital structure. For this purpose, the mounted structure body according to the third embodiment is constituted as shown in FIG. 26. As shown in FIG. 26, stacked in order on a Si substrate, for example, are the undoped GaN layer 11, the AlₓGa₁₋ₓN layer 12, the undoped GaN layer 13, the p-type GaN layer 14 and the p⁺-type GaN contact layer 15 via an AlN layer with a thickness of 100 nm, for example, an AlGaN buffer layer with a thickness of 1.5 μm, etc., and thereby the polarization super junction GaN-based field effect transistor is formed as shown in FIG. 3. Thereafter, the Si substrate is removed by a method publicly known and then an isolating layer 31 is formed on an exposed surface. If the insulating layer 31 is made of, for example, organic materials such as polymide or inorganic glass materials such as SOG (spin on glass), it can be formed by spin coating etc. If a polarization super junction GaN-based field effect transistor is formed on a sapphire substrate, it is desired that the sapphire substrate is thinned to a thickness of about 100 nm. In this case, it is not necessary to remove the substrate, which is different from a case where the Si substrate is used, and to form the insulating layer 31 and the sapphire substrate itself serves as the insulating layer 31. The source electrode 18 and the drain electrode 19 are formed like a metal pillar with a height of about several μm to 10 μm by plating. On the other hand, metal layers 33, 34 that are patterned as almost the same size as the source electrode 18 and the drain electrode 19 are formed on the submount substrate 32, and further solder layers 35 (or solder balls) are formed on the metal layers 33, 34. And the solder layers 35 of the submount substrate 32 are aligned with the source electrode 18 and the drain electrode 19 and made to come in contact with them. As the submount substrate 32, for example, a Si substrate, a SiC substrate, a diamond substrate, a BeO substrate, a CuW substrate, a CuMo substrate, a Cu substrate, an AlN substrate, etc. can be used. And when a substrate other than insulating substrates is used, an insulating film, preferably with a high thermal conductivity, such as an AlN film is formed on the major surface of the substrate on which the metal layers 33, 34 are formed. In this state, the solder layers 35 are melted by heating, so that the source electrode 18 and the drain electrode 19 and the metal layers 33, 34 are bonded. At this time, because the source electrode 18 and the drain electrode 19 and the metal layers 33, 34 are self-aligned one another by the surface tension of the molten solder, no alignment accuracy are required. A commercially available die mounter can be used. Here, although the width of the ohmic electrodes, that is, the width of the source electrode 18 and the drain electrode 19 is necessary to be the width permitting alignment by a general die mounter with patterns of the metal layers 33, 34 on the submount substrate 32, generally the width equal to or larger than 20 μm is enough. In the mounted structure body, heat generated from the polarization super junction field effect transistor during the operation is rapidly conducted to the submount substrate 32 via the source electrode 18, the drain electrode 19, the solder layers 35 and the metal layers 33, 34, and finally, radiated to the outside from the submount substrate 32. It should be noted that only one of the source electrode 18 and the drain electrode 19 (for example, only the drain electrode 19) may be connected with the submount substrate 32 via the metal layer 33 or the metal layer 34. In this case, it is also possible to finally radiate heat from the submount substrate 32 effectively.

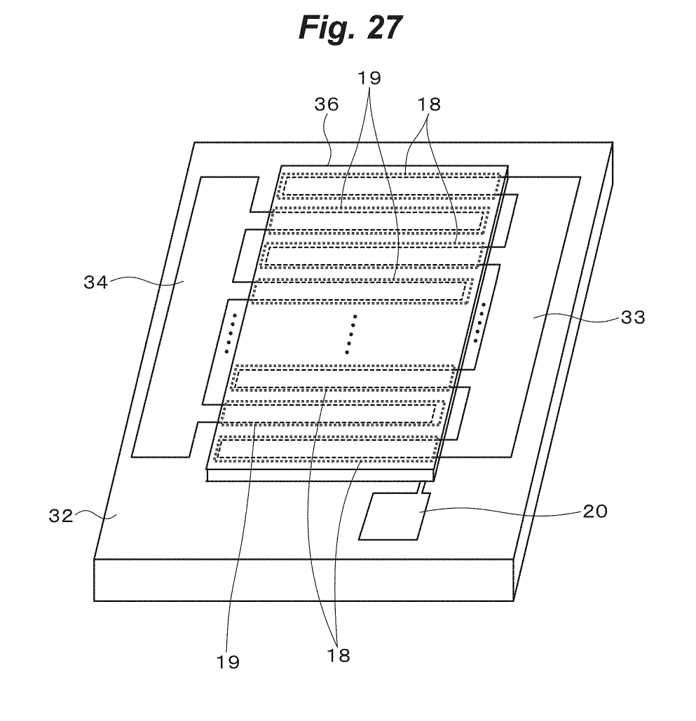

FIG. 27 shows an example of the whole image of the chip 36 constituting the polarization super junction GaN-based field effect transistor and the submount substrate 32. The metal layers 33, 34 on the submount substrate 32 are formed like the teeth of a comb respectively, and connected with the finger-like source electrode 18 and the finger-like drain electrode 19 formed on the chip 36 as patterns apart from each other, respectively. A wide lead electrode pad for wire bonding is formed on the metal layers 33, 34 outside of the chip 36. A wide lead electrode pad for wire bonding is formed on one edge of the p-electrode 20 which is led out outside the chip 36. In this case, it is not necessary to form the lead electrode pad on the chip 36, and therefore the area of the wire bonding can be saved. And it is possible to make the chip 36 small accordingly, resulting in reduction of cost of making the polarization super junction GaN-based field effect transistor.

As described above, according to the third embodiment, by combining the polarization super junction GaN-based field effect transistor according to the first embodiment and the flip chip technology, the novel mounted structure body can be realized. The mounted structure body has the following advantages. That is, because the chip 36 constituting the polarization super junction GaN-based field effect transistor is flip chip mounted on the submount substrate 32, heat generated from the chip 36 during the operation can be rapidly conducted to the submount substrate 32 and radiated to the outside from the submount substrate 32 effectively. Therefore, it is possible to prevent the temperature of the chip 36 from increasing. In addition, the voltage applied to the polarization super junction GaN-based field effect transistor is not limited and the GaN-based field effect transistor with super high resistance voltage higher than 600V can be realized. On the other hand, as the base substrate used for crystal growth, not only a sapphire substrate but also a Si substrate can be used. Furthermore, because an area for a lead electrode pad on the side of the device is not necessary to form in the chip 36, the size of the chip can be decreased to the size of the intrinsic area. As described above, according to the third embodiment, new values never obtained before can be given to the polarization super junction GaN-based field effect transistor as a lateral high current device. The conventional GaN-based HFET using the field plate technology can never realize that.

### 4. The Fourth Embodiment

In the fourth embodiment, as the same as the third embodiment, described is the mounted structure body in which a chip constituting the polarization super junction GaN-based field effect transistor or the polarization super junction GaN-based bidirectional field effect transistor according to any one of the first and the second embodiments is flip chip mounted on a mount substrate.

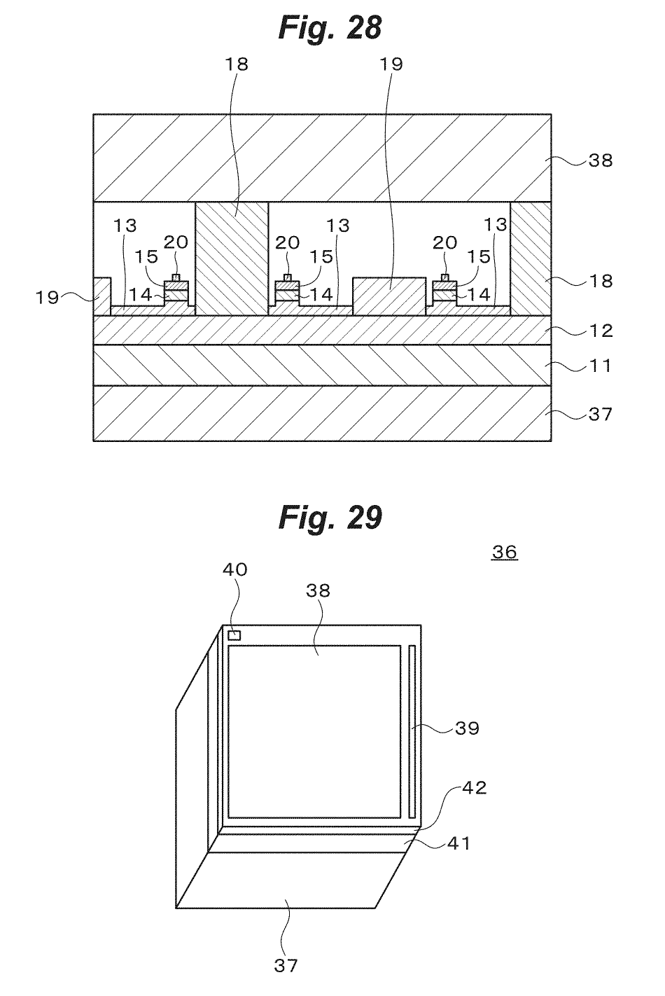

The mounted structure body according to the fourth embodiment is constituted as shown in FIG. 28. That is, in the mounted structure body, the chip 36 constituting the polarization super junction GaN-based field effect transistor has a structure shown in FIG. 28. The chip 36 is formed as follows. Stacked in order on a C-plane sapphire substrate 37 are the undoped GaN layer 11, the AlₓGa₁₋ₓN layer 12, the undoped GaN layer 13, the p-type GaN layer 14 and the p⁺-type GaN contact layer 15 via a GaN buffer layer grown in low temperature (not illustrated) and thereby the polarization super junction GaN-based field effect transistor is formed as shown in FIG. 3. Thereafter the C-plane sapphire substrate 37 is thinned to a thickness of about 100 μm. As different from the mounted structure body according to the third embodiment, a metal layer 38 is formed like an air bridge wiring with plating etc. in a state where it is directly connected with the upper surface of the several finger-like source electrodes 18. The metal layer 38 is made of, for example, Au. On the other hand, each one end of the several finger-like drain electrodes 19 extends over the outside area of the metal layer 38 and another metal layer (not illustrated) is formed like an air bridge wiring with plating etc. in a state where it is directly connected with the upper surface of the one end. Furthermore, each one end of the several finger-like p-electrodes 20 extends over the outside area of the metal layer 38 and still another metal layer (not illustrated) is formed like an air bridge wiring with plating etc. in a state where it is directly connected with the upper surface of the one end. These metal layers are also made of, for example, Au.

FIG. 29 shows an example of the chip 36 formed in this way. As shown in FIG. 29, the metal layer 38 connected with the source electrode 18 has a nearly square shape. A thin metal layer 39 connected with the drain electrode 19 are formed parallel to one side of the square metal layer 38. A rectangular metal layer 40 connected with the p-electrode 20 is formed near one edge of another side of the metal layer 38. In FIG. 29, all of the undoped GaN layer 11, the AlₓGa₁₋ₓN layer 12, the undoped GaN layer 13, the p-type GaN layer 14 and the p⁺-type GaN contact layer 15 is illustrated as a GaN-based semiconductor layer 41 and all of the source electrode 18, the drain electrode 19 and the p-electrode 20 is illustrated as an electrode layer 42.

Described now is an example of a method of mounting the chip 36 shown FIG. 29 on the submount substrate 32. As shown in FIG. 30, in this example, used is the submount substrate 32 in which an insulating film 32b such as a SiN film etc. is formed on a Cu substrate 32a and electrodes 32c, 32d, 32e for connecting with the source electrode 18, the drain electrode 19 and the p-electrode 20 of the polarization super junction GaN-based field effect transistor are formed thereon. The chip 36 shown in FIG. 29 in which the solder layer 35 is formed on the metal layers 38, 39, 40, respectively is made come in contact with the electrodes 32c, 32d, 32e in a state where the solder layer 35 is aligned with the electrodes 32c, 32d, 32e, respectively. In this state, the solder layers 35 are melted by heating, so that the metal layers 38, 39, 40 and the electrodes 32c, 32d, 32e are bonded.

Using the mounted structure body in which the chip 36 constituting the polarization super junction GaN-based field effect transistor is flip chip mounted on the submount substrate 32, an experiment of continuous energization of the polarization super junction GaN-based field effect transistor was carried out. In the experiment, the mounted structure body was attached to a Peltier device such that the Cu substrate 32a of the submount substrate 32 faces the Peltier device. Temperature of the polarization super junction GaN-based field effect transistor was set to 15° C. with the Peltier device. In this state, the drain voltage V_{d} of 0.65V was applied to the polarization super junction GaN-based field effect transistor and the initial drain current I_{d} of 8 A was continuously flowed between the source electrode 18 and the drain electrode 19. Initial input power was 8×0.65=5.1 W. Change in time of the drain current I_{d} and temperature of the polarization super junction GaN-based field effect transistor was measured. The result is shown in FIG. 31. As shown in FIG. 31, the drain current I_{d} continued to decrease for dozens of seconds after the beginning of continuous energization and then stabilized at about 6.6 A. Current reduction ratio in this time was about 18%. On the other hand, temperature of the polarization super junction GaN-based field effect transistor rapidly increased for initial dozens of seconds in time, then increased gently and reached 35° C. after about 310 seconds. Voltage resistance of the polarization super junction GaN-based field effect transistor exceeded 1100V and on-resistance Rₒₙ was about 85 mΩ. For comparison, using a commercial super junction power MOS transistor (rated voltage 650V, Rₒₙ=62 mΩ) a similar experiment was carried out. In this case, for initial input power=4 W (initial drain current=8 A, drain voltage V_{d}=0.5V), temperature increased to 36° C. and current reduction ration of the drain current I_{d} was 23%. From the result, it is understood that the polarization super junction GaN-based field effect transistor has more excellent characteristics than the commercial super junction power MOS transistor, taking everything into consideration.

According to the fourth embodiment, following advantages can be obtained in addition to the same advantages as the third embodiment. That is, in the mounted structure body, the source electrodes 18 are mutually connected by the metal layer 38, the drain electrodes 19 are mutually connected by the metal layer 39, the p-electrodes 20 are mutually connected by the metal layer 40 and the metal layers 38, 39, 40 and the electrodes 32c, 32d, 32e of the submount substrate 32 are bonded. Therefore, wire bonding is not necessary and it is possible to reduce cost and improve reliability. In addition, according to the mounted structure body, it is not necessary to form wide lead electrode pad parts for wire bonding of the metal layers 33, 34, 35 on the submount substrate 32 as the mounted structure body according to the third embodiment. Therefore, it is possible to reduce the area of the submount substrate 32 drastically and reduce cost more.

### 5. The Fifth Embodiment

In the fifth embodiment, as the same as the third embodiment, described is the mounted structure body in which a chip constituting the polarization super junction GaN-based field effect transistor or the polarization super junction GaN-based bidirectional field effect transistor according to any one of the first and the second embodiments is flip chip mounted on a mount substrate.

The mounted structure body according to the fifth embodiment is constituted as shown in FIG. 32. That is, in the mounted structure body, the chip 36 constituting the polarization super junction GaN-based field effect transistor has a structure shown in FIG. 32. The chip 36 has almost the same structure as the third embodiment, but is different from the third embodiment in the following points. That is, the source electrode 18 and the drain electrode 19 are formed like a metal pillar, but its height is smaller than the third embodiment, for example, a little larger than the p-electrode 20. Conventionally known electrically insulating materials, for example, underfill materials (composite resin with epoxy resin as main composition etc.) or passivation materials such as dielectrics (SiO₂ etc.) are filled in a space between the source electrode 18 and the drain electrode 19 which are adjacent to each other to a height as the same as the p-electrode 20 to form a filling layer 43. On the other hand, the metal layers 33, 34 which are patterned to almost the same size as the source electrode 18 and the drain electrode 19 are formed on the submount substrate 32, the solder layer 35 (or solder ball) is formed on the metal layers 33, 34, and electrically insulating materials with high thermal conductivity are filled in a space between the metal layer 33 and the solder layer 35 thereon and the metal layer 34 and the solder layer 35 thereon which are adjacent to the former two layers to a height larger than the solder layer 35 to form a high thermal conductivity layer 44. And the solder layers 35 of the submount substrate 32 are made come in contact with the source electrode 18 and the drain electrode 19 in a state where the solder layers 35 are aligned with the source electrode 18 and the drain electrode 19. As the electrically insulating materials with high thermal conductivity, for example, AlN etc. can be used. As the same as the third embodiment, in this state, the solder layers 35 are melted by heating, so that the source electrode 18 and the drain electrode 19 and the metal layers 33, 34 are bonded. The high thermal conductivity layer 44 and the p-electrode 20 are in contact with each other in a state where the source electrode 18 and the drain electrode 19 and the metal layers 33, 34 are bonded. In this state, a space between the source electrode 18, the solder layer 35 and the metal layer 33 and the drain electrode 19, the solder layer 35 and the metal layer 34 which are adjacent to the former three layers is filled with the filling layer 43 and the high thermal conductivity layer 44 and therefore the polarization super junction GaN-based field effect transistor is sealed. In the mounted structure body, heat generated from the polarization super junction field effect transistor in operation is rapidly conducted to the submount substrate 32 via the source electrode 18, the drain electrode 19, the solder layer 35, the metal layers 33, 34 and the high thermal conductivity layer 44, and finally, radiated to the outside from the submount substrate 32.

Other than the above is the same as the third embodiment.

According to the fifth embodiment, following advantages can be obtained in addition to the same advantage as the third embodiment. That is, in the mounted structure body, the high thermal conductivity layer 44 is formed in the space between the metal layer 33 and the solder layer 35 thereon and the adjacent metal layer 34 and the solder layer 35 thereon so as to fill the space. Therefore, it is possible to conduct heat generated from the polarization super junction field effect in operation to the submount substrate 32 also via the high thermal conductivity layer 44. As a result, it is possible to conduct heat generated from the polarization super junction field effect transistor in operation to the submount substrate 32 more quickly. And therefore, it is possible to radiate heat to the outside more efficiently from the submount substrate 32.

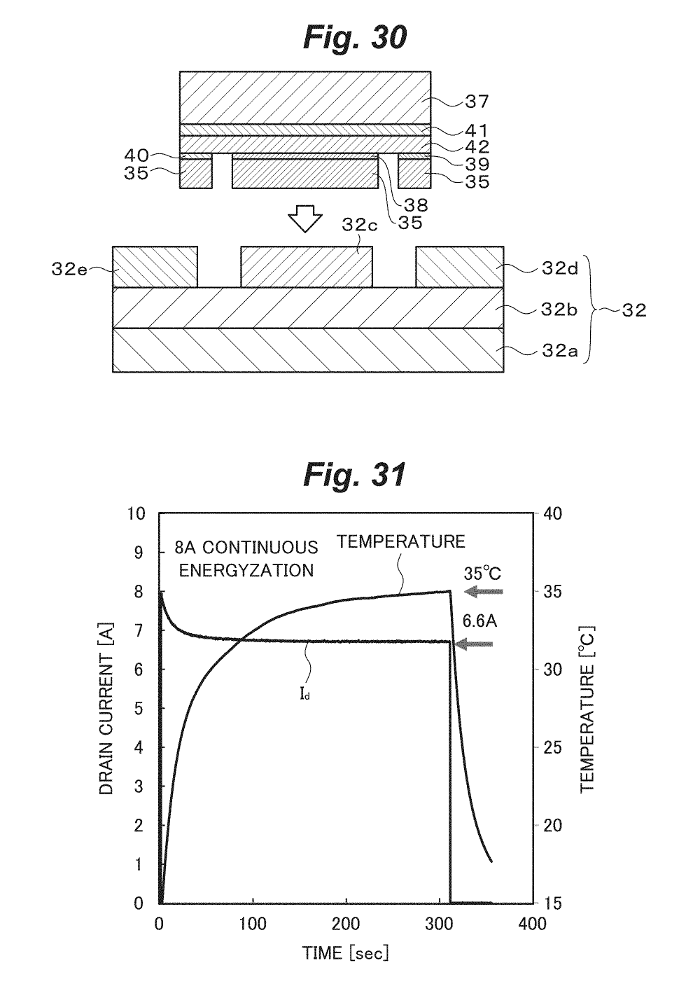

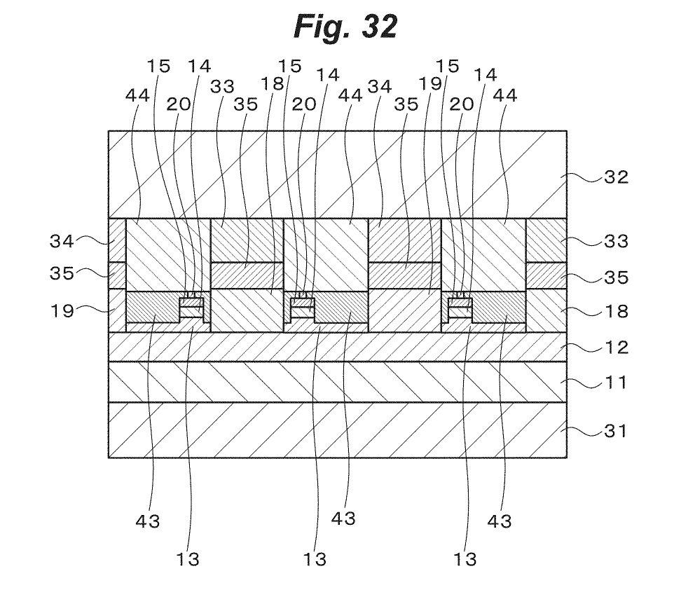

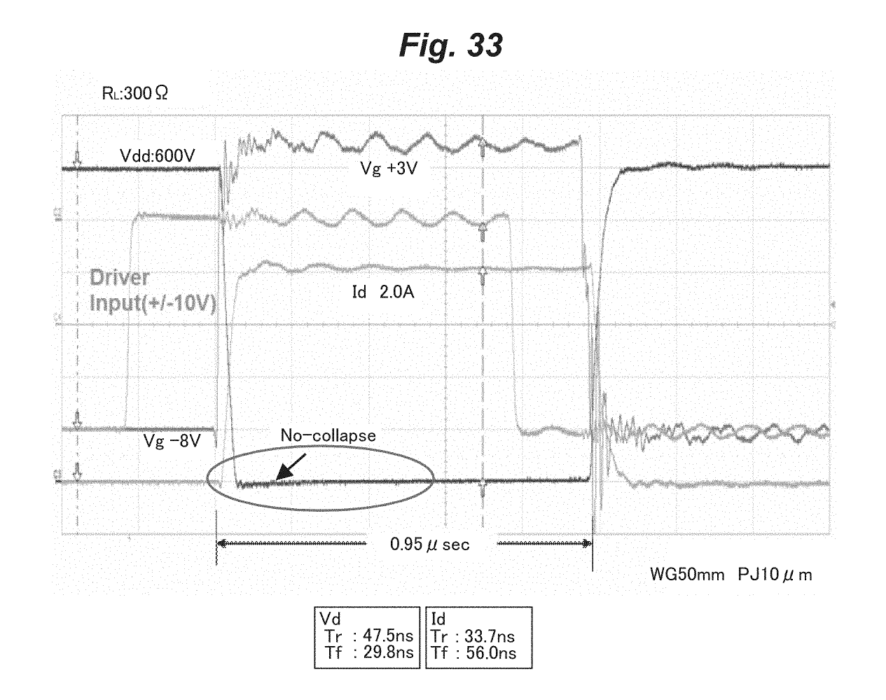

The polarization super junction GaN-based field effect transistor with the structure shown in FIG. 3 which is described in the first embodiment was made. Using a circuit in which a resistor of 300Ω is connected with the polarization super junction GaN-based transistor as a load, switching characteristic of the polarization super junction GaN-based transistor was measured. The result is now described. Pulse time is 0.95 μsec. FIG. 33 shows the result. Transition time of rise and fall is defined as 10%-90% change time. As shown in FIG. 33, although the line voltage (Vdd) was a large voltage of 600V, rise time and fall time of the drain voltage during the turn-on period were 30 nsec and 48 nsec, respectively, which are very sharp. In addition, rise time and fall time of the drain current were 34 nsec and 36 nsec, respectively, which are very fast. A very excellent switching characteristic was obtained. As shown in arrows in FIG. 33, no collapse was seen. Such an excellent switching characteristic was never obtained heretofore.

Heretofore, embodiments of the present invention have been explained specifically. However, the present invention is not limited to these embodiments, but contemplates various changes and modifications based on the technical idea of the present invention.

For example, numerical numbers, structures, shapes, materials, etc. presented in the aforementioned embodiments are only examples, and the different numerical numbers, structures, shapes, materials, etc. may be used as needed.

For example, in the polarization super junction GaN-based field effect transistors shown in FIG. 3, the undoped GaN layer 13 may be extended until its end surface comes in contact with the drain electrode 19. With this, because the undoped GaN layer 13 functions as a surface passivation film (cap layer) of the AlₓGa₁₋ₓN layer 12, the surface stability of the AlₓGa₁₋ₓN layer 12 can be improved, resulting an improvement of the characteristics of the polarization super junction GaN-based field effect transistors. For the same purpose, in the polarization super junction GaN-based diode shown in FIG. 23A, the undoped GaN layer 13 may be extended until its end surface comes in contact with the anode electrode 22. Furthermore, for the same purpose, in the polarization super junction GaN-based bidirectional field effect transistor shown in FIG. 24, the undoped GaN layer 13 may be extended until its end surface comes in contact with the first electrode 24a and the second electrode 24b. As needed, in the polarization super junction GaN-based field effect transistor shown in FIG. 3, the polarization super junction GaN-based diodes shown in FIG. 23A and FIG. 23B and the polarization super junction GaN-based bidirectional field effect transistor shown in FIG. 24, all of the exposed surface of the AlₓGa₁₋ₓN layer 12 may be covered by the undoped GaN layer 13.

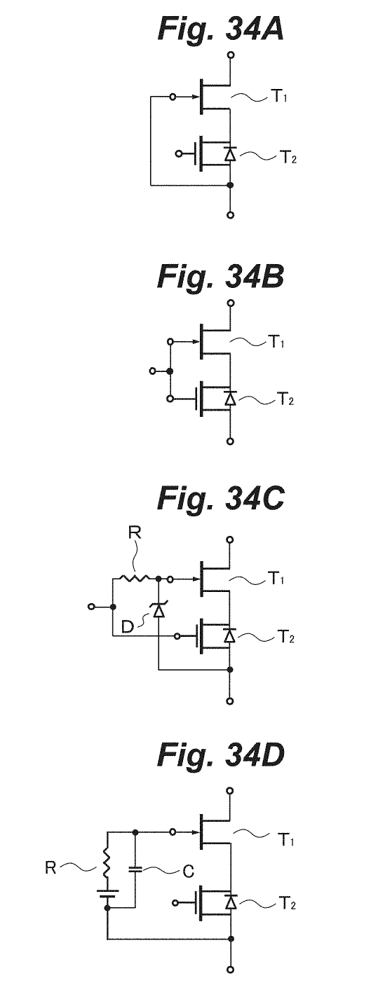

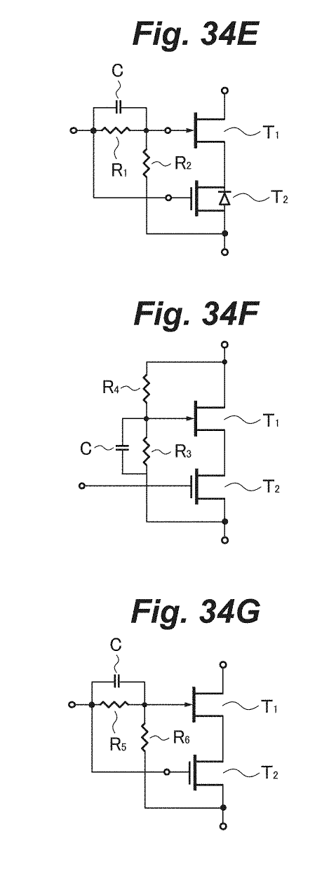

The normally-on field effect transistor of the polarization super junction GaN-based semiconductor element according to the first embodiment can be changed into the one of normally-off type by mounting a cascode circuit publicly known with a low-priced low resistance voltage Si transistor. FIG. 34A shows a cascode circuit using a normally-on field effect transistor T₁ and a low resistance voltage normally-off Si MOS transistor T₂. FIG. 34B shows a modified cascode circuit using the normally-on field effect transistor T₁ and the low resistance voltage normally-off Si MOS transistor T₂. FIG. 34C shows a modified cascode circuit using the normally-on field effect transistor T₁, the low resistance voltage normally-off SiMOS transistor T₂, a Schottky diode D and a resistor R. FIG. 34D shows a modified cascode circuit using the normally-on field effect transistor T₁, the low resistance voltage normally-off Si MOS transistor T₂, a capacitor C and the resistor R. FIG. 34E shows a modified cascade circuit using the normally-on field effect transistor T₁, the low resistance voltage SiMOS transistor T₂, a capacitor C and resistors R₁, R₂. In the cascode circuit shown in FIG. 34A, the gate voltage (V_{gs}) during the turn-on period of the normally-on field effect transistor T₁ on the side of the high resistance voltage is 0V. In the normally-on field effect transistor T₁, it is effective to apply a positive gate voltage. For the purpose, it is effective to use the modified cascode circuit shown in FIG. 34B, FIG. 34C, FIG. 34D or FIG. 34E. It is also effective to use the cascade circuit shown in FIG. 34F. As shown in FIG. 34F, the cascode circuit is constituted by the normally-on field effect transistor T₁, the low resistance voltage normally-off SiMOS transistor T₂, a capacitor C and resistors R₃, R₄. The cascode circuit supplies power from the drain side. As shown in FIG. 34G, it is also effective to use a modified cascode circuit using the normally-on field effect transistor T₁, the low resistance voltage normally-off SiMOS transistor T₂, a capacitor C and resistors R₅, R₆. It is also possible to use the cascode circuit or the modified cascode circuit and place a gate driver in a package by the technology publicly known heretofore.

### EXPLANATION OF REFERENCE NUMERALS

10 C-plane sapphire substrate
11 Undoped GaN layer
12 AlₓGa₁₋ₓN layer
13 Undoped GaN layer
14,14a,14b p-type GaN layer
15,15a,15b p⁺-type GaN contact layer
16 Two-dimensional hole gas
17 Two-dimensional electron gas
18 Source electrode
19 Drain electrode
20,20a,20b p-electrode
22 Anode electrode
23 Cathode electrode
24a First electrode
24b Second electrode
36 Chip

1. A semiconductor element, comprising:
a polarization super junction region, comprising a first undoped GaN layer, an AlₓGa₁₋ₓN layer on the first undoped GaN layer and a second undoped GaN layer on the AlₓGa₁₋ₓN layer, no p-type GaN layer being provided on the second undoped GaN layer; and
a p-electrode contact region provided separately from the polarization super junction region,
the Al composition x and the thickness t [nm] of the AlₓGa₁₋ₓN layer satisfying the following equation
t≧α(a)x^{β(a)}
where the thickness of the second undoped GaN layer is denoted as a [nm] (a is not smaller than 10 nm and not larger than 1000 nm),
α is expressed as
Log (α)=p₀+p₁ log (a)+p₂{log (a)}²
(p₀=7.3295, p₁=−3.5599, p₂=0.6912) and
β is expressed as
β=p′₀+p′₁ log (a)+p′₂{log (a)}²
(p′₀=−3.6509, p′₁=1.9445, p′₂=−0.3793),
the polarization super junction region and the p-electrode contact region including the first undoped GaN layer, the AlₓGa₁₋ₓN layer and the second undoped GaN layer as common layers,
the p-electrode contact region, further comprising a Mg-doped p-type GaN layer on the second undoped GaN layer, a p-type GaN contact layer which is doped with Mg heavier than the p-type GaN layer, provided in contact with the p-type GaN layer and a p-electrode which is in ohmic contact with the p-type GaN contact layer, the p-type GaN layer, the p-type GaN contact layer and the p-electrode being provided only in the p-electrode contact region.

2. The semiconductor element according to claim 1 wherein the semiconductor element is a field effect transistor, the second undoped GaN layer on the AlₓGa₁₋ₓN layer has an island shape, the p-type GaN layer and the p-type GaN contact layer are formed as a mesa, a source electrode and a drain electrode are formed on the AlₓGa₁₋ₓN layer so as to sandwich the second undoped GaN layer and the p-electrode forms a gate electrode.

3. The semiconductor element according to claim 1 wherein the semiconductorelement is a diode, the second undoped GaN layer on the AlₓGa₁₋ₓN layer has an island shape, the p-type GaN layer and the p-type GaN contact layer are formed as a mesa, an anode electrode and a cathode electrode are formed on the AlₓGa₁₋ₓN layer so as to sandwich the second undoped GaN layer and the anode electrode and the p-electrode are electrically connected each other.

4. Electric equipment, comprising:
at least a semiconductor element, comprising:
the semiconductor element being
a semiconductor element, comprising:
a polarization super junction region, comprising a first undoped GaN layer, an AlₓGa₁₋ₓN layer on the first undoped GaN layer and a second undoped GaN layer on the AlₓGa₁₋ₓN layer, no p-type GaN layer being provided on the second undoped GaN layer; and
a p-electrode contact region provided separately from the polarization super junction region,
the Al composition x and the thickness t [nm] of the AlₓGa₁₋ₓN layer satisfying the following equation
t≧α(a)x^{β(a)}
where the thickness of the second undoped GaN layer is denoted as a [nm] (a is not smaller than 10 nm and not larger than 1000 nm),
α is expressed as
Log (α)=p₀+p₁ log (a)+p₂{log (a)}²
(p₀=7.3295, p₁=−3.5599, p₂=0.6912) and
β is expressed as
β=p′₀+p′₁ log (a)+p′₂{log (a)}²
(p′₀=−3.6509, p′₁=1.9445, p′₂=−0.3793),
the polarization super junction region and the p-electrode contact region including the first undoped GaN layer, the AlₓGa₁₋ₓN layer and the second undoped GaN layer as common layers,
the p-electrode contact region, further comprising a Mg-doped p-type GaN layer on the second undoped GaN layer, a p-type GaN contact layer which is doped with Mg heavier than the p-type GaN layer, provided in contact with the p-type GaN layer and a p-electrode which is in ohmic contact with the p-type GaN contact layer, the p-type GaN layer, the p-type GaN contact layer and the p-electrode being provided only in the p-electrode contact region.

5. The electric equipment according to claim 4 wherein the semiconductor element is a field effect transistor, the second undoped GaN layer on the AlₓGa₁₋ₓN layer has an island shape, the p-type GaN layer and the p-type GaN contact layer are formed as a mesa, a source electrode and a drain electrode are formed on the AlₓGa₁₋ₓN layer so as to sandwich the second undoped GaN layer and the p-electrode forms a gate electrode.

6. The electric equipment according to claim 4 wherein the semiconductorelement is a diode, the second undoped GaN layer on the AlₓGa₁₋ₓN layer has an island shape, the p-type GaN layer and the p-type GaN contact layer are formed as a mesa, an anode electrode and a cathode electrode are formed on the AlₓGa₁₋ₓN layer so as to sandwich the second undoped GaN layer and the anode electrode and the p-electrode are electrically connected each other.

7. A bidirectional field effect transistor, comprising:
A polarization super junction region and a p-electrode contact region which are provided separately each other,
the polarization super junction region, comprising a first undoped GaN layer, an AlₓGa₁₋ₓN layer on the first undoped GaN layer and an island-like second undoped GaN layer on the AlₓGa₁₋ₓN layer, no p-type GaN layer being provided on the second undoped GaN layer,
the Al composition x and the thickness t [nm] of the AlₓGa₁₋ₓN layer satisfying the following equation
t≧α(a)^{β(a)}
where the thickness of the second undoped GaN layer is denoted as a [nm] (a is not smaller than 10 nm and not larger than 1000 nm),
α is expressed as
Log (α)=p₀+p₁ log (a)+p₂{log (a)}²
(p₀=7.3295, p₁=−3.5599, and p₂=0.6912) and
β is expressed as
β=p′₀+p′₁ log (a)+p′₂{log (a)}²
(p′₀=−3.6509, p′₁=1.9445, and p′₂=−0.3793),
the polarization super junction region and the p-electrode contact region including the first undoped GaN layer, the AlₓGa₁₋ₓN layer and the second undoped GaN layer as common layers,
a first electrode and a second electrode constituting a source electrode or a drain electrode being provided on the AlₓGa₁₋ₓN layer so as to sandwich the second undoped GaN layer,
the p-electrode contact region, comprising:
a Mg-doped first p-type GaN layer on the second undoped GaN layer,
a Mg-doped second p-type GaN layer on the second undoped GaN layer, provided separately from the first p-type GaN layer,
a first p-type GaN contact layer which is doped with Mg heavier than the first p-type GaN layer, provided in contact with the first p-type GaN layer,
a second p-type GaN contact layer which is doped with Mg heavier than the second p-type GaN layer, provided in contact with the second p-type GaN layer,
a first p-electrode constituting a first gate electrode which is in ohmic contact with the first p-type GaN contact layer; and
a second p-electrode constituting a second gate electrode which is in ohmic contact with the second p-type GaN contact layer,
the first p-type GaN layer, the second p-type GaN layer, the first p-type GaN contact layer, the second p-type GaN contact layer, the first p-electrode and the second p-electrode being provided only in the p-electrode contact region.

8. Electric equipment, comprising:
one or more bidirectional switches,
at least one of the bidirectional switches being
a bidirectional field effect transistor, comprising:
a polarization super junction region and a p-electrode contact region which are provided separately each other,
the polarization super junction region, comprising a first undoped GaN layer, an AlₓGa₁₋ₓN layer on the first undoped GaN layer and an island-like second undoped GaN layer on the AlₓGa₁₋ₓN layer, no p-type GaN layer being provided on the second undoped GaN layer,
the Al composition x and the thickness t [nm] of the AlₓGa₁₋ₓN layer satisfying the following equation
t≧α(a)x^{β(a)}
where the thickness of the second undoped GaN layer is denoted as a [nm] (a is not smaller than 10 nm and not larger than 1000 nm),
α is expressed as
Log (α)=p₀+p₁ log (a)+p₂{log (a)}²
(p₀=7.3295, p₁=−3.5599, and p₂=0.6912) and
β is expressed as
β=p′₀+p′₁ log (a)+p′₂{log (a)}²
(p′₀=−3.6509, p′₁=1.9445, and p′₂=−0.3793),
the polarization super junction region and the p-electrode contact region including the first undoped GaN layer, the AlₓGa₁₋ₓN layer and the second undoped GaN layer as common layers,
a first electrode and a second electrode constituting a source electrode or a drain electrode being provided on the AlₓGa₁₋ₓN layer so as to sandwich the second undoped GaN layer,
the p-electrode contact region, comprising:
a Mg-doped first p-type GaN layer on the second undoped GaN layer,
a Mg-doped second p-type GaN layer on the second undoped GaN layer, provided separately from the first p-type GaN layer,
a first p-type GaN contact layer which is doped with Mg heavier than the first p-type GaN layer, provided in contact with the first p-type GaN layer,
a second p-type GaN contact layer which is doped with Mg heavier than the second p-type GaN layer, provided in contact with the second p-type GaN layer,
a first p-electrode constituting a first gate electrode which is in ohmic contact with the first p-type GaN contact layer; and
a second p-electrode constituting a second gate electrode which is in ohmic contact with the second p-type GaN contact layer,
the first p-type GaN layer, the second p-type GaN layer, the first p-type GaN contact layer, the second p-type GaN contact layer, the first p-electrode and the second p-electrode being provided only in the p-electrode contact region.

9. A mounted structure body, comprising:
a chip constituting a semiconductor element; and
a mount board on which the chip is flip chip mounted,
the semiconductor element being
a polarization super junction region comprising a first undoped GaN layer, an AlₓGa₁₋ₓN layer on the first undoped GaN layer and a second undoped GaN layer on the AlₓGa₁₋ₓN layer, no p-type GaN layer being provided on the second undoped GaN layer; and
a p-electrode contact region provided separately from the polarization super junction region,
the Al composition x and the thickness t [nm] of the AlₓGa₁₋ₓN layer satisfying the following equation
t≧α(a)x^{β(a)}
where the thickness of the second undoped GaN layer is denoted as a [nm] (a is not smaller than 10 nm and not larger than 1000 nm),
α is expressed as
Log (α)=p₀+p₁ log (a)+p₂{log (a)}²
(p₀=7.3295, p₁=−3.5599, p₂=0.6912) and
β is expressed as
β=p′₀+p′₁ log (a)+p′₂{log (a)}²
(p′₀=−3.6509, p′₁=1.9445, p′₂=−0.3793),
the polarization super junction region and the p-electrode contact region including the first undoped GaN layer, the AlₓGa₁₋ₓN layer and the second GaN layer as common layers,
the p-electrode contact region, further comprising a Mg-doped p-type GaN layer on the second undoped GaN layer, a p-type GaN contact layer which is doped with Mg heavier than the p-type GaN layer, provided in contact with the p-type GaN layer and a p-electrode which is in ohmic contact with the p-type GaN contact layer, the p-type GaN layer, the p-type GaN contact layer and the p-electrode being provided only in the p-electrode contact region.

10. The mounted structure body according to claim 9 wherein the semiconductor element is a field effect transistor, the second undoped GaN layer on the AlₓGa₁₋ₓN layer has an island shape, the p-type GaN layer and the p-type GaN contact layer are formed as a mesa, a source electrode and a drain electrode are formed on the AlₓGa₁₋ₓN layer so as to sandwich the second undoped GaN layer and the p-electrode forms a gate electrode.

11. The mounted structure body according to claim 9 wherein the semiconductor element is a diode, the second undoped GaN layer on the AlₓGa₁₋ₓN layer has an island shape, the p-type GaN layer and the p-type GaN contact layer are formed as a mesa, an anode electrode and a cathode electrode are formed on the AlₓGa₁₋ₓN layer so as to sandwich the second undoped GaN layer and the anode electrode and the p-electrode are electrically connected each other.

12. A mounted structure body, comprising:
a chip constituting a semiconductor element; and
a mount board on which the chip is flip chip mounted,
the semiconductor element being
a bidirectional field effect transistor, comprising:
a polarization super junction region and a p-electrode contact region which are provided separately each other,
the polarization super junction region, comprising a first undoped GaN layer, an AlₓGa₁₋ₓN layer on the first undoped GaN layer and an island-like second undoped GaN layer on the AlₓGa₁₋ₓN layer,
the Al composition x and the thickness t [nm] of the AlₓGa₁₋ₓN layer satisfying the following equation
t≧α(a)x^{β(a)}
where the thickness of the second undoped GaN layer is denoted as a [nm] (a is not smaller than 10 nm and not larger than 1000 nm),
α is expressed as
Log (α)=p₀+p₁ log (a)+p₂{log (a)}²
(p₀=7.3295, p₁=−3.5599, and p₂=0.6912) and
β is expressed as
β=p′₀+p′₁ log (a)+p′₂{log (a)}²
(p′₀=−3.6509, p′₁=1.9445, and p′₂=−0.3793),
the polarization super junction region and the p-electrode contact region including the first undoped GaN layer, the AlₓGa₁₋ₓN layer and the second undoped GaN layer as common layers,
a first electrode and a second electrode constituting a source electrode or a drain electrode being provided on the AlₓGa₁₋ₓN layer so as to sandwich the second undoped GaN layer,
the p-electrode contact region, comprising:
a Mg-doped first p-type GaN layer on the second undoped GaN layer,
a Mg-doped second p-type GaN layer on the second undoped GaN layer, provided separately from the first p-type GaN layer,
a first p-type GaN contact layer which is doped with Mg heavier than the first p-type GaN layer, provided in contact with the first p-type GaN layer,
a second p-type GaN contact layer which is doped with Mg heavier than the second p-type GaN layer, provided in contact with the second p-type GaN layer,
a first p-electrode constituting a first gate electrode which is in ohmic contact with the first p-type GaN contact layer; and
a second p-electrode constituting a second gate electrode which is in ohmic contact with the second p-type GaN contact layer,
the first p-type GaN layer, the second p-type GaN layer, the first p-type GaN contact layer, the second p-type GaN contact layer, the first p-electrode and the second p-electrode being provided only in the p-electrode contact region.
